(19) United States
(12) Patent Application Publication
(10) Pub. No.: US 2026/0344140 A1
(43) Pub. Date: Oct. 29, 2026

(54) LIGHT-EMITTING DEVICE, DISPLAY APPARATUS INCLUDING THE SAME, AND METHOD OF MANUFACTURING LIGHT-EMITTING DEVICE

(71) Applicant: SAMSUNG ELECTRONICS CO., LTD., Suwon-si (KR)

(72) Inventors: Junhee CHOI, Suwon-si (KR); Nakhyun Kim, Suwon-si (KR); Kiho Kong, Suwon-si (KR); Dongchul Shin, Suwon-si (KR); Joohun Han, Suwon-si (KR)

(73) Assignee: SAMSUNG ELECTRONICS CO., LTD., Suwon-si (KR)

(21) Appl. No.: 19/440,192

(22) Filed: Jan. 5, 2026

(30) Foreign Application Priority Data
Apr. 24, 2025 (KR) 10-2025-0054099

(51) Int. Cl. H10H 29/14; H10H 20/813; H10H 20/84; H10H 29/80

(52) U.S. Cl. CPC H10H 29/14; H10H 20/8131; H10H 20/84; H10H 29/8321

(57) ABSTRACT

Provided is a light-emitting device including a first light-emitting portion including a first emission structure, a second light-emitting portion including first and second emission structures, a third light-emitting portion including first through third emission structures, a first common electrode, and a second common electrode, the first and second emission structures of the second light-emitting portion and the first through third emission structures of the third light-emitting portion spaced apart, each of the first through third emission structures includes a first conductive-type semiconductor layer, an active layer, and a second conductive-type semiconductor layer, wherein the first emission structures include a common first conductive-type semiconductor layer, the first common electrode connects the common first conductive-type semiconductor layer to a first conductive-type semiconductor layer of the third light-emitting portion, and the second common electrode connects the common first conductive-type semiconductor layer to the first conductive-type semiconductor layer of the second light-emitting portion.

### CROSS-REFERENCE TO RELATED APPLICATION

This application is based on and claims priority under 35 U.S.C. §119 to Korean Patent Application No. 10-2025-0054099, filed on Apr. 24, 2025, in the Korean Intellectual Property Office, the disclosure of which is incorporated by reference herein in its entirety.

### BACKGROUND

### 1. Field

The disclosure relates to a light-emitting device, a display apparatus including the same, and a method of manufacturing the light-emitting device.

### 2. Description of Related Art

A light-emitting device, e.g., a light-emitting diode (LED), is a next-generation light source having such advantages such as longer lifespan, low power consumption, fast response speed, and eco-friendliness as compared with a light source of the related art, and owing to the above advantages, industrial needs for the LED are increasing. An LED is generally applied to various products such as an illumination device, a display apparatus, etc.

Recently, an ultra-small sized LED of a micro-unit or nano-unit has been developed, and is referred to as a micro-LED. A micro-LED is applied to a relatively large-sized display apparatus such as a television, etc., and moreover, has been attempted to be applied to a relatively small-sized display apparatus such as a display in an augmented reality (AR) device, etc. In a micro-LED in which red-green-blue (RGB) sub-pixels are arranged vertically, a light-emitting area decreases due to electrodes having conductive via structures for driving respective sub-pixels, and thus, the light-emitting efficiency of the micro-LED may degrade.

### SUMMARY

Provided are a light-emitting device in which sub-pixels are arranged horizontally, a display apparatus including the same, and a method of manufacturing the light-emitting device.

Additional aspects will be set forth in part in the description which follows and, in part, will be apparent from the description, or may be learned by practice of the presented embodiments of the disclosure.

According to an aspect of one or more embodiments, there is provided a light-emitting device including a first light-emitting portion including a first emission structure, a second light-emitting portion including a first emission structure and a second emission structure that are sequentially stacked, a third light-emitting portion including a first emission structure, a second emission structure, and a third emission structure that are sequentially stacked, a first common electrode, and a second common electrode, wherein the first light-emitting portion, the second light-emitting portion, and the third light-emitting portion are spaced apart from each other, wherein each of the first emission structure of the first light-emitting portion, the first emission structure and the second emission structure of the second light-emitting portion, and the first emission structure, the second emission structure, and the third emission structure of the third light-emitting portion includes a first conductive-type semiconductor layer, an active layer, and a second conductive-type semiconductor layer that are sequentially stacked, wherein the first emission structure of the first light-emitting portion, the first emission structure of the second light-emitting portion, and the first emission structure of the third light-emitting portion include a common first conductive-type semiconductor layer, wherein the first common electrode electrically connects the common first conductive-type semiconductor layer to a first conductive-type semiconductor layer in the third emission structure of the third light-emitting portion, and the first common electrode includes a first electrode material, and wherein the second common electrode is configured to electrically connect the common first conductive-type semiconductor layer to the first conductive-type semiconductor layer of the second emission structure of the second light-emitting portion, the second common electrode comprises a second electrode material different from the first electrode material.

The first electrode material and the second electrode material may have etch selectivity with respect to different etchants.

A surface of the first conductive-type semiconductor layer, exposed between the first light-emitting portion, the second light-emitting portion, and the third light-emitting portion, may be flat.

The first common electrode may extend from the exposed surface of the common first conductive-type semiconductor layer along a side surface of the third light-emitting portion and contacts a side surface of the first conductive-type semiconductor layer of the third emission structure of the third light-emitting portion, and the second common electrode may extend from the exposed surface of the common first conductive-type semiconductor layer along a side surface of the second light-emitting portion and contacts the side surface of the first conductive-type semiconductor layer of the second emission structure of the second light-emitting portion.

The first common electrode and the second common electrode may partially overlap each other between the second light-emitting portion and the third light-emitting portion.

The light-emitting device may further include interlayer insulating layers between the first emission structure and the second emission structure of the second light-emitting portion and between adjacent pairs from among the first emission structure, the second emission structure, and the third emission structure of the third light-emitting portion.

The second conductive-type semiconductor layer forming an uppermost layer of the first light-emitting portion and the second conductive-type semiconductor layer forming an uppermost layer of the second light-emitting portion may be surface-treated with a second conductive-type dopant.

A surface dopant concentration of the second conductive-type semiconductor layers that are surface-treated may be greater than or equal to 3×10²⁰ cm⁻³.

The light-emitting device may further include a passivation layer on the first light-emitting portion, the second light-emitting portion, the third light-emitting portion, the first common electrode, and the second common electrode, the passivation layer having openings that expose an upper surface of the second conductive-type semiconductor layer at an uppermost layer of the first light-emitting portion, an upper surface of the second conductive-type semiconductor layer at an uppermost layer of the second light-emitting portion, and an upper surface of the second conductive-type semiconductor layer at an uppermost layer of the third light-emitting portion, and a first individual electrode, a second individual electrode, and a third individual electrode may contact the upper surface of the second conductive-type semiconductor layer at the uppermost layer of the first light-emitting portion, the upper surface of the second conductive-type semiconductor layer at the uppermost layer of the second light-emitting portion, and the upper surface of the second conductive-type semiconductor layer at the uppermost layer of the third light-emitting portion, respectively, via the openings.

The first individual electrode, the second individual electrode, and the third individual electrode may extend from the upper surface of the second conductive-type semiconductor layer at the uppermost layer of the first light-emitting portion, the upper surface of the second conductive-type semiconductor layer at the uppermost layer of the second light-emitting portion, and the upper surface of the second conductive-type semiconductor layer at the uppermost layer of the third light-emitting portion along a side surface of the passivation layer.

According to another aspect of one or more embodiments, there is provided a method of manufacturing a light-emitting device, the method including forming an epitaxial structure including a first emission structure, a second emission structure, and a third emission structure, each of the first emission structure, the second emission structure, and the third emission structure including a first conductive-type semiconductor layer, an active layer, and a second conductive-type semiconductor layer that are sequentially stacked, forming a first epitaxial structure, a second epitaxial structure, and a third epitaxial structure that are spaced apart from each other by etching the epitaxial structure to the first conductive-type semiconductor layer of the first emission structure, exposing the second conductive-type semiconductor layer of the first emission structure of the first epitaxial structure, the second conductive-type semiconductor layer of the second emission structure of the second epitaxial structure, and the second conductive-type semiconductor layer of the third emission structure of the third epitaxial structure, forming a first common electrode extending from an exposed surface of the first conductive-type semiconductor layer of the first emission structure and contacting a side surface of the first conductive-type semiconductor layer of the third emission structure in the third epitaxial structure, the first common electrode including a first electrode material, and forming a second common electrode extending from an exposed surface of the first conductive-type semiconductor layer of the first emission structure and contacting a side surface of the first conductive-type semiconductor layer of the second emission structure in the second epitaxial structure, the second common electrode including a second electrode material different from the first electrode material.

The exposing of the second conductive-type semiconductor layer of the first emission structure of the first epitaxial structure, the second conductive-type semiconductor layer of the second emission structure of the second epitaxial structure, and the second conductive-type semiconductor layer of the third emission structure of the third epitaxial structure may include exposing the second conductive-type semiconductor layer of the third emission structure of the first epitaxial structure, the second conductive-type semiconductor layer of the third emission structure of the second epitaxial structure, and the second conductive-type semiconductor layer of the third emission structure of the third epitaxial structure, exposing the second conductive-type semiconductor layer of the second emission structure of the first epitaxial structure and the second conductive-type semiconductor layer of the second emission structure of the second epitaxial structure by removing the third emission structure of the first epitaxial structure and the third emission structure of the second epitaxial structure, and exposing the second conductive-type semiconductor layer of the first emission structure in the first epitaxial structure by removing the second emission structure of the first epitaxial structure.

The forming the epitaxial structure may include forming etch stop layers having different etching speeds between adjacent pairs from among the first emission structure, the second emission structure, and the third emission structure.

The forming the first common electrode may include forming a first electrode material layer by depositing the first electrode material on the first epitaxial structure, the second epitaxial structure, and the third epitaxial structure and an exposed surface of the first conductive-type semiconductor layer of the first emission structure, and removing the first electrode material on an upper surface of the first epitaxial structure, the upper surface of the second epitaxial structure, and an upper surface of the third epitaxial structure by a first etchant having an etch selectivity with respect to the first electrode material.

The forming the second common electrode may include forming a second electrode material layer by depositing the second electrode material on the first epitaxial structure, the second epitaxial structure, the third epitaxial structure, the first common electrode, and an exposed surface of the first conductive-type semiconductor layer of the first emission structure, and removing, in the second electrode material layer, a part on the first epitaxial structure, a part on the upper surface of the second epitaxial structure, and a part on the third epitaxial structure, and a portion of a part on the first common electrode by a second etchant having an etch selectivity with respective to the second electrode material.

From among the exposed second conductive-type semiconductor layer of the first epitaxial structure, the exposed second conductive-type semiconductor layer of the second epitaxial structure, and the exposed second conductive-type semiconductor layer of the third epitaxial structure, at least the second conductive-type semiconductor layer forming uppermost layer of the first epitaxial structure and the second conductive-type semiconductor layer forming an uppermost layer of the second epitaxial structure are surface-treated by a second conductive-type dopant.

A surface dopant concentration of the second conductive-type semiconductor layers that are surface-treated may be greater than or equal to 3×10²⁰ cm⁻³.

The method may further include forming a passivation layer on the first epitaxial structure, the second epitaxial structure, the third epitaxial structure, the first common electrode, and the second common electrode, the passivation layer having openings exposing an upper surface of the second conductive-type semiconductor layer at an uppermost layer of the first epitaxial structure, an upper surface of the second conductive-type semiconductor layer at an uppermost layer of the second epitaxial structure, and an upper surface of the second conductive-type semiconductor layer at an uppermost layer of the third epitaxial structure, and forming a first individual electrode, a second individual electrode, and a third individual electrode that contact the upper surface of the second conductive-type semiconductor layer at the uppermost layer of the first emission structure, the upper surface of the second conductive-type semiconductor layer at the uppermost layer of the second emission structure, and the upper surface of the second conductive-type semiconductor layer at the uppermost layer of the third emission structure, respectively, via the openings.

The first individual electrode, the second individual electrode, and the third individual electrode may extend from the upper surface of the second conductive-type semiconductor layer at the uppermost layer of the first epitaxial structure, the upper surface of the second conductive-type semiconductor layer at the uppermost layer of the second epitaxial structure, and the upper surface of the second conductive-type semiconductor layer at the uppermost layer of the third epitaxial structure along a side surface of the passivation layer.

According to yet another aspect of one or more embodiments, there is provided a display apparatus including a display panel including light-emitting devices, a drive circuit configured to switch the light-emitting devices on and off, and at least one processor configured to input switching signal for the light-emitting devices to the drive circuit based on an image signal, wherein at least one of the light-emitting devices includes a first light-emitting portion including a first emission structure, a second light-emitting portion including a first emission structure and a second emission structure that are sequentially stacked, a third light-emitting portion including a first emission structure, a second emission structure, and a third emission structure that are sequentially stacked, a first common electrode, and a second common electrode, wherein the first emission light-emitting portion, the second light-emitting portion, and the third light-emitting portion are spaced apart from each other, and the third emission structure of the third light-emitting portion are spaced apart from each other, wherein each of the first emission structure of the first light-emitting portion, the first emission structure and the second emission structure of the second light-emitting portion, and the first emission structure, the second emission structure, and the third emission structure of the third light-emitting portion includes a first conductive-type semiconductor layer, an active layer, and a second conductive-type semiconductor layer that are sequentially stacked, wherein the first emission structure of the first light-emitting portion, the first emission structure of the second light-emitting portion, and the first emission structure of the third light-emitting portion include a common first conductive-type semiconductor layer, wherein the first common electrode electrically connects the common first conductive-type semiconductor layer to a first conductive-type semiconductor layer in the third emission structure of the third light-emitting portion, and the first common electrode includes a first electrode material, and wherein the second common electrode is configured to electrically connect the common first conductive-type semiconductor layer to the first conductive-type semiconductor layer of the second emission structure of the second light-emitting portion, the second common electrode comprises a second electrode material different from the first electrode material.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a plan view of a light-emitting device according to one or more embodiments;

FIG. 1B is a cross-sectional view of a light-emitting device according to one or more embodiments;

FIG. 2 is a cross-sectional view of a light-emitting device according to one or more embodiments;

FIG. 3 is a cross-sectional view of a light-emitting device according to one or more embodiments;

FIG. 4 is a cross-sectional view of a light-emitting device according to one or more embodiments;

FIG. 5 is a cross-sectional view of a display panel according to one or more embodiments;

FIG. 6A is a flowchart illustrating a method of manufacturing a light-emitting device, according to one or more embodiments;

FIG. 6B is a flowchart illustrating a method of manufacturing a light-emitting device including first, second, and third light-emission portions, according to one or more embodiments;

FIGS. 7A, 7B, 7C, 7D, 7E, 7F, 7G, 7H, 7I, 7J, 7K, 7L, 7M, 7N, 7, 7P, 7Q, 7R, 7S, 7T, 7U, 7V, 7W, 7X, and 7Y are diagrams illustrating a method of manufacturing a light-emitting device, according to one or more embodiments;

FIGS. 8A, 8B, 8C, 8D, 8E, 8F, 8G, 8H, 8I, 8J, 8K, and 8L are diagrams illustrating a method of manufacturing a light-emitting device, according to one or more embodiments;

FIG. 9A is a diagram showing a passivation layer being formed;

FIG. 9B is a diagram showing individual electrodes being formed;

FIGS. 10A, 10B, 10C, 10D, 10E, and 10F are diagrams illustrating a method of manufacturing a display panel, according to one or more embodiments;

FIG. 11 is a schematic diagram of a display apparatus according to one or more embodiments;

FIG. 12 is a block diagram of an electronic device including a display, according to one or more embodiments;

FIG. 13 is a diagram showing an example of a mobile device that is an example of the electronic device;

FIG. 14 is a diagram showing a head-up display apparatus for a vehicle, according to an application example of the electronic device;

FIG. 15 is a diagram showing augmented reality (AR) glasses or virtual reality (VR) glasses, according to an application example of the electronic device;

FIG. 16 is a diagram showing large-sized signage according to an application example of the electronic device; and

FIG. 17 is a diagram showing a wearable display according to an application example of the electronic device.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, a light-emitting device and a display apparatus adopting the same according to embodiments are described in detail below with reference to accompanying drawings. In the drawings, like reference numerals denote like components, and sizes of components in the drawings may be exaggerated for convenience of explanation. The embodiments of the disclosure are capable of various modifications and may be embodied in many different forms.

Hereinafter, it will be understood that when a layer, region, or component is referred to as being “above” or “on” another layer, region, or component, it may be in contact with and directly on the other layer, region, or component, and intervening layers, regions, or components may be present. An expression used in the singular encompasses the expression of the plural, unless it has a clearly different meaning in the context. It will be further understood that when a portion is referred to as “comprising” another component, the portion may not exclude another component but may further comprise another component unless the context states otherwise.

The use of the terms of “the above-described” and similar indicative terms may correspond to both the singular forms and the plural forms. Also, the steps of all methods described herein may be performed in any suitable order unless otherwise indicated herein or otherwise clearly contradicted by context.

Furthermore, the connecting lines or connectors shown in the drawings are intended to represent example functional relationships and/or physical or logical couplings between the various elements. It should be noted that many alternative or additional functional relationships, physical connections, or logical connections may be present in a practical device.

The use of any and all examples, or example language provided herein, is intended merely to better illuminate the disclosure and does not pose a limitation on the scope of the present disclosure unless otherwise claimed.

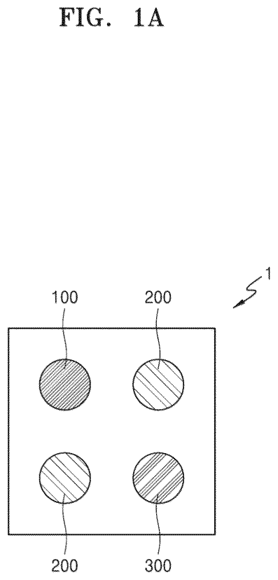

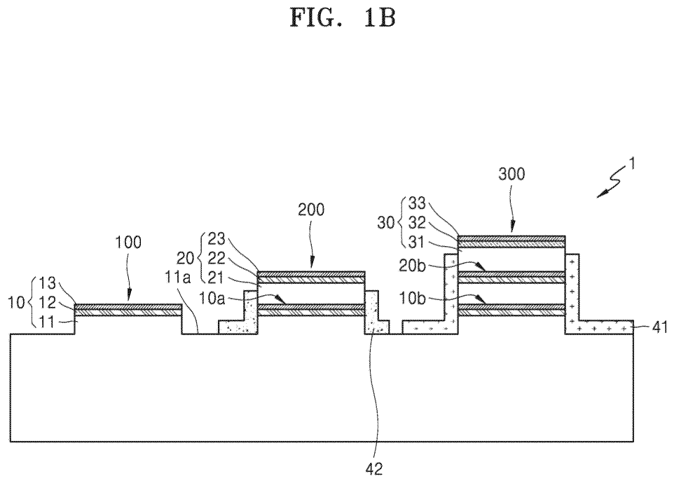

FIG. 1A is a schematic plan view of a light-emitting device 1 according to one or more embodiments. FIG. 1B is a schematic cross-sectional view of the light-emitting device 1 according to one or more embodiments. The light-emitting device 1 of the embodiment is a horizontal-type light-emitting device in which sub-pixels are horizontally arranged. The light-emitting device 1 may correspond to one pixel, but is not limited thereto, and a plurality of light-emitting devices 1 may correspond to one pixel. The light-emitting device 1 may be referred to as, for example, a micro-LED.

The light-emitting device 1 may include a plurality of light-emitting portions spaced apart from one another. Each of the plurality of light-emitting portions includes one or more emission structures emitting light. Each emission structure may include a first conductive-type semiconductor layer, an active layer having a quantum-well structure, and a second conductive-type semiconductor layer, that are epitaxially grown in a vertical direction. The plurality of light-emitting portions may have different numbers of stacks of the emission structures. The plurality of light-emitting portions may include two or more light-emitting portions having the same number of stacks of the emission structures. The plurality of light-emitting portions may emit light when the uppermost emission structure, from among one or more emission structures included therein, is activated. The plurality of light-emitting portions may emit light of different wavelengths from the uppermost emission structures, from among one or more emission structures included therein. The plurality of light-emitting portions may have two or more light-emitting portions having the same uppermost emission structures. For example, when the plurality of light-emitting portions form one pixel, the plurality of light-emitting portions may have two or more light-emitting portions emitting light of the same color.

The lowermost emission structure in each of the plurality of light-emitting portions has a common first conductive-type semiconductor layer. The uppermost emission structure in each of the plurality of light-emitting portions is an active emission structure. A plurality of common electrodes electrically connect the common first conductive-type semiconductor layer to the first conductive-type semiconductor layers in the uppermost emission structures in the plurality of light-emitting portions. The plurality of common electrodes do not pass through the emission structures in the plurality of light-emitting portions. For example, the plurality of common electrodes may extend from an exposed surface of the common first conductive-type semiconductor layer along the side surfaces of the plurality of light-emitting portions, and then may come into contact with the side surfaces of the first conductive-type semiconductor layers in the uppermost emission structures respectively in the plurality of light-emitting portions. The plurality of individual electrodes are electrically connected to (contact) second conductive-type semiconductor layers in the uppermost emission structures of the plurality of light-emitting portions, respectively. The plurality of individual electrodes do not pass through the emission structures in the plurality of light-emitting portions. Accordingly, a common voltage is applied to the common first conductive-type semiconductor layer and a driving voltage is selectively applied to the plurality of individual electrodes, and thus, the uppermost emission structures in the plurality of light-emitting portions may be selectively activated and emit light. The plurality of common electrodes include an electrode material. At least one of the plurality of common electrodes may include an electrode material that is different from those of the other common electrodes. The two electrode materials may have etch selectivity with respect to different etchants.

At least some of the second conductive-type semiconductor layers in the uppermost emission structures of the plurality of light-emitting portions may be surface-treated by a second conductive type dopant.

For example, referring to FIGS. 1A and 1B, the plurality of light-emitting portions may include a first light-emitting portion 100, a second light-emitting portion 200, and a third light-emitting portion 300. The first light-emitting portion 100 may include a first emission structure 10. The second light-emitting portion 200 may include a first emission structure 10a and a second emission structure 20 that are sequentially stacked. The third light-emitting portion 300 may include a first emission structure 10b, a second emission structure 20b, and a third emission structure 30 that are sequentially stacked. The first, second, and third light-emitting portions 100, 200, and 300 are arranged to be spaced apart from one another. The first emission structures 10 of the first, second, and third light-emitting portions 100, 200, and 300 have a common first conductive-type semiconductor layer 11. For example, the first emission structures 10, 10a, 10b of the first, second, and third light-emitting portions 100, 200, and 300 may be formed by arranging active layers 12 and second conductive-type semiconductor layers 13 on the common first conductive-type semiconductor layer 11, at positions spaced apart from each other.

Each of the plurality of light-emitting portions has an uppermost emission structure that is an active emission structure. For example, the first emission structure 10 in the first light-emitting portion 100, the second emission structure 20 in the second light-emitting portion 200, and the third emission structure 30 in the third light-emitting portion 300 are respectively active emission structures. The first, second, and third emission structures 10, 20, and 30 may include a group III-V nitride semiconductor material. The group III-V nitride semiconductor material may include, for example, gallium nitride (GaN), indium gallium nitride (InGaN), aluminum indium gallium nitride (AlInGaN), aluminum gallium indium phosphide (AlGaInP), etc. For example, the first, second, and third emission structures 10, 20, and 30 may include a GaN-based semiconductor material. In the active layer of each of the first, second, and third emission structures 10, 20, and 30, bandgap energy is controlled according to the composition ratio of indium (In) in a material layer including In, and thus, a light-emitting wavelength band may be determined. The first, second, and third emission structures 10, 20, and 30 may emit light of different wavelengths. In a non-limiting example, the first, second, and third emission structures 10, 20, and 30 may respectively emit blue light (e.g., light having a wavelength range of 460±20 nm), green light (e.g., light having a wavelength range of 530±20 nm), and red light (e.g., light having a wavelength range of 630±20 nm). The light-emitting device 1 may form one pixel. In FIG. 1A, the light-emitting device 1 may include one first light-emitting portion 100 emitting blue light, one third light-emitting portion 300 emitting red light, and two second light-emitting portions 200 emitting green light, but is not limited thereto. The first, second, and third light-emitting portions 100, 200, and 300 may emit light of different wavelength bands, rather than the blue light, green light, and red light. Also, the light-emitting device 1 may further include a light-emitting portion emitting light of other wavelength bands than the blue light, green light, and red light. The light-emitting device 1 may include three light-emitting portions. The light-emitting device 1 may include five or more light-emitting portions. Five or more light-emitting portions may include two or more light-emitting portions emitting light of the same wavelength band. The arrangement of the plurality of light-emitting portions included in one light-emitting device 1 is not limited to the example shown in FIG. 1A.

Referring to FIG. 1B, the first light-emitting portion 100 includes the first emission structure 10. The first emission structure 10 may include a first conductive-type semiconductor layer 11, an active layer 12 having a quantum-well structure, and a second conductive-type semiconductor layer 13 that are sequentially stacked. The first conductive-type semiconductor layer 11 may include a semiconductor layer doped with a first conductive-type dopant (e.g., n-type dopant), e.g., n-GaN layer. Silicon (Si), germanium (Ge), selenium (Se), telluride (Te), etc. may be used as the n-type dopant. The active layer 12 is a layer emitting light through recombination of electrons-holes. The active layer 12 may be grown on the first conductive-type semiconductor layer 11. The active layer 12 has a quantum-well structure. For example, the active layer 12 may include a multi-quantum-well structure formed by periodically changing x, y, and z values in AlₓGa_{y}In_{z}N and adjusting a band gap. For example, a quantum-well layer and a barrier layer may form the quantum-well structure as a pair in the form of InGaN/GaN, InGaN/InGaN, InGaN/AlGaN, or InGaN/InAlGaN, and the band gap energy may be controlled and the light-emission wavelength band may be adjusted according to the composition ratio of indium (In) in the material layer including In. The second conductive-type semiconductor layer 13 may be formed on the active layer 12. The second conductive-type semiconductor layer 13 may be a semiconductor layer doped with a second conductive-type dopant (e.g., p-type dopant), e.g., a p-GaN layer. magnesium (Mg), zinc (Zn), beryllium (Be), etc. may be used as the p-type dopant.

The second light-emitting portion 200 includes a first emission structure 10a and the second emission structure 20 stacked on the first emission structure 10a. The first emission structure 10a may include a first conductive-type semiconductor layer 11, an active layer 12 having a quantum-well structure, and a second conductive-type semiconductor layer 13 that are sequentially stacked. The first emission structure 10a of the second light-emitting portion 200 shares the first conductive-type semiconductor layer 11 with the first emission structure 10 of the first light-emitting portion 100. The above descriptions about the first conductive-type semiconductor layer 11, the active layer 12, and the second conductive-type semiconductor layer 13 of the first emission structure 10 in the first light-emitting portion 100 may be applied to the first conductive-type semiconductor layer 11, the active layer 12, and the second conductive-type semiconductor layer 13 of the first emission structure 10a in the second light-emitting portion 200. The second emission structure 20 may include a first conductive-type semiconductor layer 21, the active layer 22 having a quantum-well structure, and the second conductive-type semiconductor layer 23 that are sequentially stacked. The above descriptions about the first conductive-type semiconductor layer 11, the active layer 12, and the second conductive-type semiconductor layer 13 of the first emission structure 10 in the first light-emitting portion 100 may be applied to the first conductive-type semiconductor layer 21, the active layer 22, and the second conductive-type semiconductor layer 23 of the second emission structure 20 in the second light-emitting portion 200.

The third light-emitting portion 300 includes a first emission structure 10b, a second emission structure 20b stacked on the first emission structure 10b, and a third emission structure 30 stacked on the second emission structure 20b. The first emission structure 10b may include a first conductive-type semiconductor layer 11, an active layer 12 having a quantum-well structure, and a second conductive-type semiconductor layer 13 that are sequentially stacked. The first emission structure 10b of the third light-emitting portion 300 shares the first conductive-type semiconductor layer 11 with the first emission structure 10 of the first light-emitting portion 100 and the first emission structure 10a of the second light-emitting portion 200. Therefore, the first emission structures 10, 10a, and 10b of the first, second, and third light-emitting portions 100, 200, and 300 have a common first conductive-type semiconductor layer 11. The above descriptions about the first conductive-type semiconductor layer 11, the active layer 12, and the second conductive-type semiconductor layer 13 of the first emission structure 10 in the first light-emitting portion 100 may be applied to the first conductive-type semiconductor layer 11, the active layer 12, and the second conductive-type semiconductor layer 13 of the first emission structure 10b in the third light-emitting portion 300. The second emission structure 20b may include the first conductive-type semiconductor layer 21, the active layer 22 having a quantum-well structure, and the second conductive-type semiconductor layer 23 that are sequentially stacked. The above descriptions about the first conductive-type semiconductor layer 11, the active layer 12, and the second conductive-type semiconductor layer 13 of the first emission structure 10 in the first light-emitting portion 100 may be applied to the first conductive-type semiconductor layer 21, the active layer 22, and the second conductive-type semiconductor layer 23 of the second emission structure 20b in the third light-emitting portion 300. The third emission structure 30 may include a first conductive-type semiconductor layer 31, an active layer 32 having a quantum-well structure, and a second conductive-type semiconductor layer 33 that are sequentially stacked. The above descriptions about the first conductive-type semiconductor layer 11, the active layer 12, and the second conductive-type semiconductor layer 13 of the first emission structure 10 in the first light-emitting portion 100 may be applied to the first conductive-type semiconductor layer 31, the active layer 32, and the second conductive-type semiconductor layer 33 of the third emission structure 30 in the third light-emitting portion 300.

The common first conductive-type semiconductor layer 11 may include exposed surfaces 11a between the first, second, and third light-emitting portions 100, 200, and 300. The exposed surface 11a may be flat.

A plurality of common electrodes may include, for example, a first common electrode 41 and a second common electrode 42. The first common electrode 41 may electrically connect the common first conductive type semiconductor layer 11 to the uppermost emission structure of the third light-emitting portion 300, e.g., the first conductive-type semiconductor layer 31 of the third emission structure 30. For example, the first common electrode 41 may extend from the exposed surface 11a of the common first conductive-type semiconductor layer 11 along the side surface of the third light-emitting portion 300 and may come into contact with the side surface of the first conductive-type semiconductor layer 31 of the third emission structure 30. In one or more embodiments, the first common electrode 41 may entirely or partially surround and/or be adjacent to the side surface of the third light-emitting portion 300. The second common electrode 42 electrically connects the common first conductive-type semiconductor layer 11 to the uppermost emission structure of the second light-emitting portion 200, e.g., the first conductive-type semiconductor layer 21 of the second emission structure 20. For example, the second common electrode 42 may extend from the exposed surface 11a of the common first conductive-type semiconductor layer 11 along the side surface of the second light-emitting portion 200 and may come into contact with the side surface of the first conductive-type semiconductor layer 21 of the second emission structure 20.

Accordingly, by applying a common voltage to the common first conductive-type semiconductor layer 11, the common voltage may be applied to the first conductive-type semiconductor layers 11, 21, and 31 of the first emission structure 10 of the first light-emitting portion 100, the second emission structure 20 of the second light-emitting portion 200, and the third emission structure 30 of the third light-emitting portion 300.

In one or more embodiments, the second common electrode 42 may entirely or partially surround and/or be adjacent to the side surface of the second light-emitting portion 200. In one or more embodiments, the first common electrode 41 and the second common electrode 42 are spaced apart from each other. For example, the first common electrode 41 and the second common electrode 42 do not overlap each other.

The first common electrode 41 and the second common electrode 42 may include an electrode material. The electrode material may include, for example, aluminum (Al), titanium (Ti), platinum (Pt), silver (Ag), gold (Au), palladium (Pd), titanium tungsten (TiW), indium tin oxide (ITO), molybdenum (Mo), or various combinations thereof. The first common electrode 41 and the second common electrode 42 may include different electrode materials. For example, the first common electrode 41 may include a first electrode material, and the second common electrode 42 may include a second electrode material. The first electrode material and the second electrode material may have etch selectivity with respect to different etchants. For example, one of the first and second electrode materials may include indium tin oxide (ITO), and the other of the first and second electrode materials may include Mo. The ITO may have etch selectivity with respect to a HCl-based etchant, e.g., product name LCE 12. Mo has an etch selectivity with respect to a perchloric acid-based etchant, e.g., product name CR-7. The combination of the first electrode material and the second electrode material is not limited thereto, and various combinations of the electrode materials having the etch selectivity with respect to different etchants may be used.

Through the above configuration, the light-emitting device 1, in which the plurality of light-emitting portions, e.g., the first, second, and third light-emitting portions 100, 200, and 300, may be horizontally arranged and the first and second common electrodes 41 and 42 may not pass through the first, second, and third light-emitting portions 100, 200, and 300, may be implemented.

In one or more embodiments, at least the second conductive-type semiconductor layers 13 and 23, from among the second conductive-type semiconductor layers 13, 23, and 33 forming the uppermost layers of the first, second, and third light-emitting portions 100, 200, and 300, may be surface-treated by a second conductive-type etchant. All of the second conductive-type semiconductor layers 13, 23, and 33 may be surface-treated with the second conductive-type dopant. The second conductive-type semiconductor layers 13 and 23 or the second conductive-type semiconductor layers 13, 23, and 33 may be surface-treated to a thickness of about, for example, 5 nm to 30 nm. A surface dopant concentration of the surface-treated second conductive type semiconductor layers 13 and 23 or the second conductive-type semiconductor layers 13, 23, and 33 may be 3×10²⁰ cm⁻³ or greater. During an etching process for forming the first, second, and third light-emitting portions 100, 200, and 300, the second conductive-type dopants of the second conductive-type semiconductor layers 13, 23, and 33 that are located at the uppermost layers of the first, second, and third light-emitting portions 100, 200, and 300 may be partially inactivated, thereby degrading a carrier providing performance of the second conductive-type semiconductor layers 13, 23, and 33. Accordingly, light-extracting efficiency may degrade. According to one or more embodiments, the second conductive-type dopants are dispersed to the inside through the exposed surfaces of the second conductive-type semiconductor layers 13 and 23 or the second conductive-type semiconductor layers 13, 23, and 33 so as to recover the dopant concentration on the second conductive-type semiconductor layers 13 and 23 or the second conductive-type semiconductor layers 13, 23, and 33 to an appropriate level, e.g., 3×10²⁰ cm⁻³ or greater. Accordingly, the production yield of the light-emitting device 1 may be improved. Also, a dispersion profile of the second conductive-type dopant may be formed on the second conductive-type semiconductor layers 13 and 23 or the second conductive-type semiconductor layers 13, 23, and 33, and thus, injection of carriers (e.g., holes) into the second conductive-type semiconductor layers 13 and 23 or the second conductive-type semiconductor layers 13, 23, and 33 is reinforced and the light-extracting efficiency and luminance of the light-emitting device 1 may increase. Also, the light-emitting device 1 as above may emit light of relatively high luminance with a relatively small size, and thus may be applied to a relatively high-resolution display panel. For example, when the second conductive-type semiconductor layers 13, 23, and 33 are p-type semiconductor layers, the second conductive-type dopant for the surface treatment may include a p-type dopant, e.g., Mg, Zn, or Be. For example, in the embodiment, Mg is used as the p-type dopant for the surface treatment.

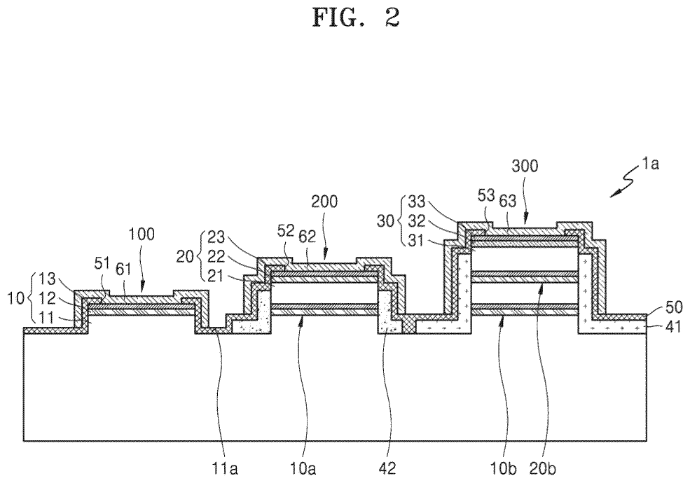

FIG. 2 is a schematic plan view of a light-emitting device 1a according to one or more embodiments. The light-emitting device 1a of the embodiment differs from the light-emitting device 1 shown in FIG. 1B, in view of including a plurality of individual electrodes. Therefore, elements performing the same functions are denoted by the same reference numerals, and repeated descriptions thereof are omitted.

Referring to FIG. 2, the light-emitting device 1a may further include a passivation layer 50 and a first individual electrode 61, a second individual electrode 62, and a third individual electrode 63. The passivation layer 50 covers and/or may be on the surfaces of the first, second, and third light-emitting portions 100, 200, and 300 and the first and second common electrodes 41 and 42. The passivation layer 50 includes openings 51, 52, and 53 respectively exposing the upper surfaces of the second conductive-type semiconductor layers 13, 23, and 33 at the uppermost layers of the first, second, and third light-emitting portions 100, 200, and 300. The passivation layer 50 may include a charge blocking layer for preventing charge diffusion through the side surfaces of the first, second, and third light-emitting portions 100, 200, and 300. The charge blocking layer may have, for example, a single-layered structure including aluminum indium nitride (AlN) or a multi-layered structure including AlN/AlOₓ. The passivation layer 50 may further include a reflective layer arranged outside the charge blocking layer. The reflective layer may have, for example, a distributed Bragg reflector (DBR) structure. The DBR structure may have a structure, for example, of stacking silicon oxide (SiO₂)/titanium oxide (TiO₂) three times.

The first, second, and third individual electrodes 61, 62, and 63 respectively come into contact with the upper surfaces of the second conductive-type semiconductor layers 13, 23, and 33 at the uppermost layers of the first, second, and third light-emitting portions 100, 200, and 300 through the openings 51, 52, and 53. The first, second, and third individual electrodes 61, 62, and 63 may each include an electrode material. The electrode material may include, for example, Al, Ti, Pt, Ag, Au, Pd, TiW, ITO, or various combinations thereof. Accordingly, by applying a common voltage to the common first conductive-type semiconductor layer 11, the common voltage may be applied to the first conductive-type semiconductor layers 11, 21, and 31 of the first emission structure 10 of the first light-emitting portion 100, the second emission structure 20 of the second light-emitting portion 200, and the third emission structure 30 of the third light-emitting portion 300. Also, by selectively applying a driving voltage to the first, second, and third individual electrodes 61, 62, and 63, the first emission structure 10 of the first light-emitting portion 100, the second emission structure 20 of the second light-emitting portion 200, and the third emission structure 30 of the third light-emitting portion 300 are selectively activated to emit light.

Through the above configuration, the light-emitting device 1a, in which the plurality of light-emitting portions, e.g., the first, second, and third light-emitting portions 100, 200, and 300, may be horizontally arranged and the first and second common electrodes 41 and 42 and the individual electrodes 61, 62, and 63 may not pass through the first, second, and third light-emitting portions 100, 200, and 300, may be implemented.

The first, second, and third individual electrodes 61, 62, and 63 may extend from the upper surfaces of the second conductive-type semiconductor layers 13, 23, and 33 at the uppermost layers of the first, second, and third light-emitting portions 100, 200, and 300 along the side surface of the passivation layer 60. For example, the first, second, and third individual electrodes 61, 62, and 63 may each partially surround and/or be adjacent to the first, second, and third light-emitting portions 100, 200, and 300. Accordingly, the first, second, and third individual electrodes 61, 62, and 63 may include an electrode material having reflectivity, e.g., Al, Ag, etc., and thus, may improve light-extracting efficiency.

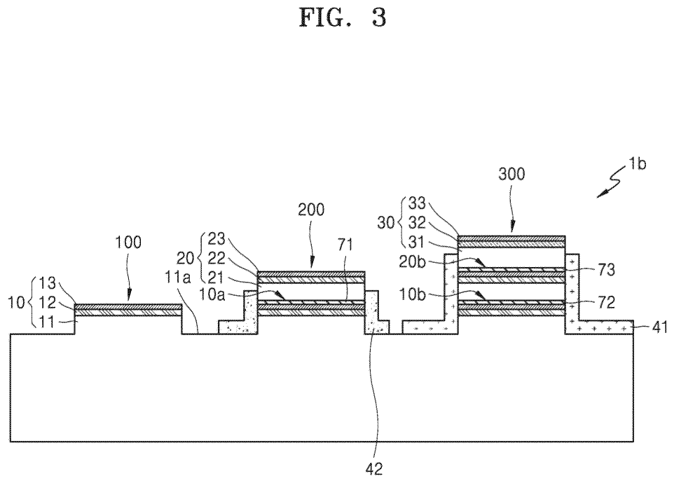

FIG. 3 is a schematic plan view of a light-emitting device 1b according to one or more embodiments. The light-emitting device 1b of the embodiment differs from the light-emitting device 1 shown in FIG. 1B in view of including an interlayer insulating layer. Therefore, elements performing the same functions are denoted by the same reference numerals, and repeated descriptions thereof are omitted.

Referring to FIG. 3, an interlayer insulating layer 71 is arranged between the first and second emission structures 10a and 20 of the second light-emitting portion 200. Also, interlayer insulating layers 72 and 73 are arranged between adjacent pairs of the first, second, and third emission structures 10b, 20b, and 30 of the third light-emitting portion 300. The interlayer insulating layers 71, 72, and 73 may each include a dielectric material. The interlayer insulating layers 71, 72, and 73 may be epitaxially grown along with the first, second, and third light-emitting portions 100, 200, and 300. To this end, the interlayer insulating layers 71, 72, and 73 may include a GaN-based dielectric material, e.g., AlGaN. The interlayer insulating layers 71, 72, and 73 may act as etch stop layers for preventing excessive etching of the second conductive-type semiconductor layers 13 and 23 in manufacturing processes described later. The passivation layer 50 and the individual electrodes 61, 62, and 63 shown in FIG. 2 may be applied to the light-emitting device 1b shown in FIG. 3.

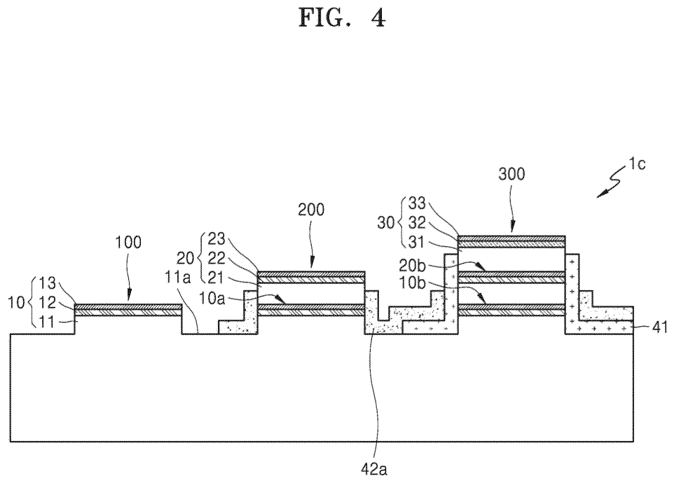

FIG. 4 is a schematic plan view of a light-emitting device 1c according to one or more embodiments. The light-emitting device 1c of the embodiment differs from the light-emitting device 1 in view of a shape of the common electrode. Therefore, elements performing the same functions are denoted by the same reference numerals, and repeated descriptions thereof are omitted.

Referring to FIG. 4, a second common electrode 42a may partially overlap the first common electrode 41. For example, the second common electrode 42a may partially overlap the first common electrode 41 between the second light-emitting portion 200 and the third light-emitting portion 300. The passivation layer 50 and the individual electrodes 61, 62, and 63 shown in FIG. 2 and the interlayer insulating layers 71, 72, and 73 shown in FIG. 3 may be also applied to the light-emitting device 1c shown in FIG. 4.

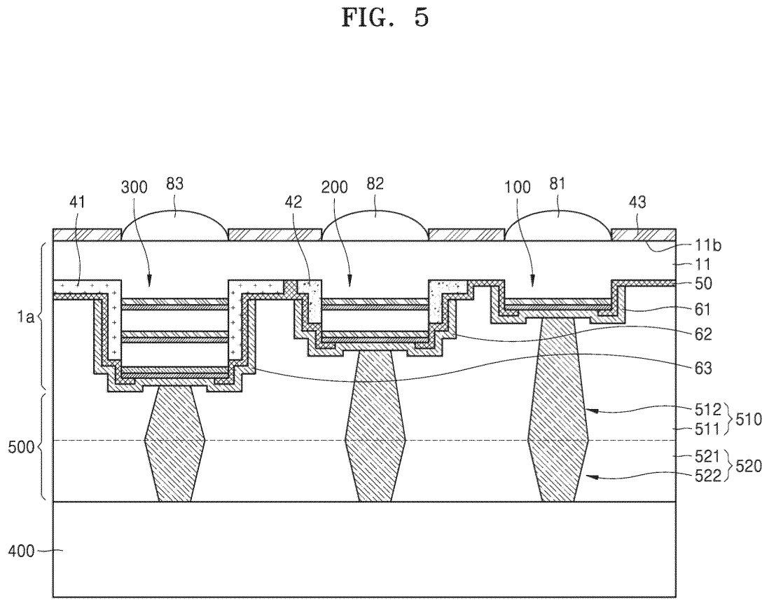

FIG. 5 is a schematic cross-sectional view of a display panel according to one or more embodiments. Referring to FIG. 5, the display panel may include the light-emitting device 1a, a driving substrate 400, and a connector 500 connecting them. A drive circuit is provided on the driving substrate 400. The connector 500 may connect the plurality of light-emitting portions, e.g., the first, second, and third light-emitting portions 100, 200, and 300, to the drive circuit of the driving substrate 400 in the individual electrodes 61, 62, and 63. The structure of the connector 500 is not particularly restricted. For example, the connector 500 may be implemented through copper-to-copper (Cu-to-Cu (C2C)) hybrid bonding.

For example, the connector 500 may include a first connector 510 and a second connector 520. The first connector 510 may include a first insulating layer 511 covering and/or on the light-emitting device 1a, and three first conductive vias 512 that are passing through the first insulating layer 511 and respectively connected to the first, second, and third individual electrodes 61, 62, and 63. The second connector 520 may include a second insulating layer 521 covering and/or on the driving substrate 400, and three second conductive vias 522 making pairs with the three first conductive vias 512 after passing through the second insulating layer 521.

The first and second insulating layers 511 and 521 may include, for example, SiO₂. First, after forming the first insulating layer 511 covering and/or on the light-emitting device 1a, a surface of the first insulating layer 511 may be polished through, for example, a chemical mechanical polishing (CMP) process. Next, through a Cu-damascene process, for example, the three first conductive vias 512 that are respectively connected to the first, second, and third individual electrodes 61, 62, and 63 through the first insulating layer 511 may be formed. The three first conductive vias 512 are exposed to the surface of the first insulating layer 511.

Next, the second insulating layer 521, for example, is formed on the driving substrate 400. After polishing the surface of the second insulating layer 521, through the Cu-damascene process, the three second conductive vias 522 making the pairs along with the three first conductive vias 512 after passing through the second insulating layer 521 may be formed.

Next, the first connector 510 and the second connector 520 are bonded to each other by a C2C hybrid bonding process. The three first conductive vias 512 are bonded to the three second conductive vias 522. Accordingly, driving signals may be applied from the drive circuit of the driving substrate 400 to the light-emitting portions 100, 200, and 300 of the light-emitting device 1a.

Referring to FIG. 5, lenses 81, 82, and 83 are shown. The lenses 81, 82, and 83 may be provided on a surface 11b of the common first conductive-type semiconductor layer 11 in a light-emitting direction. The lenses 81, 82, and 83 respectively correspond to the first, second, and third light-emitting portions 100, 200, and 300. The lenses 81, 82, and 83 may be formed by, for example, a photoresist thermosetting process. The lenses 81, 82, and 83 may adjust emitting angles of the light emitted from the first, second, and third light-emitting portions 100, 200, and 300. Accordingly, the light may be emitted from the light-emitting device 1a at a desired angle range.

Before forming the lenses 81, 82, and 83, a process of thinning the first conductive semiconductor layer 11 may be performed. Next, the lenses 81, 82, and 83 may be formed on the surface 11b in the light-emitting direction of the first conductive semiconductor layer 11. The method of forming the lenses 81, 82, and 83 is not particularly restricted. For example, a thermoplastic material may be stacked on the surface 11b of the first conductive-type semiconductor layer 11 to form a light transmission layer. For example, the thermoplastic material may include photoresist, polyester, acryl, epoxy, etc. The light transmission layer may have, for example, a cylindrical shape. Next, a thermal reflow process, for example, is performed to shape the light transmission layer of a rectangular shape into a dome-shaped lens shape. A curvature of the lenses 81, 82, and 83 may be adjusted by surface energy on the surface 11b of the first conductive-type semiconductor layer 11, a contact angle of the light emission layer, a thickness and width of the light emission layer, a temperature of the thermal reflow process, etc.

Referring to FIG. 5, a common electrode 43 is shown. The common electrode 43 may be provided on the surface 11b of the common first conductive-type semiconductor layer 11 in the light-emitting direction. The common electrode 43 may be electrically connected to the first common electrodes 41 and 42 via the common first conductive-type semiconductor layer 11.

Hereinafter, a method of manufacturing the light-emitting devices according to one or more embodiments is described below.

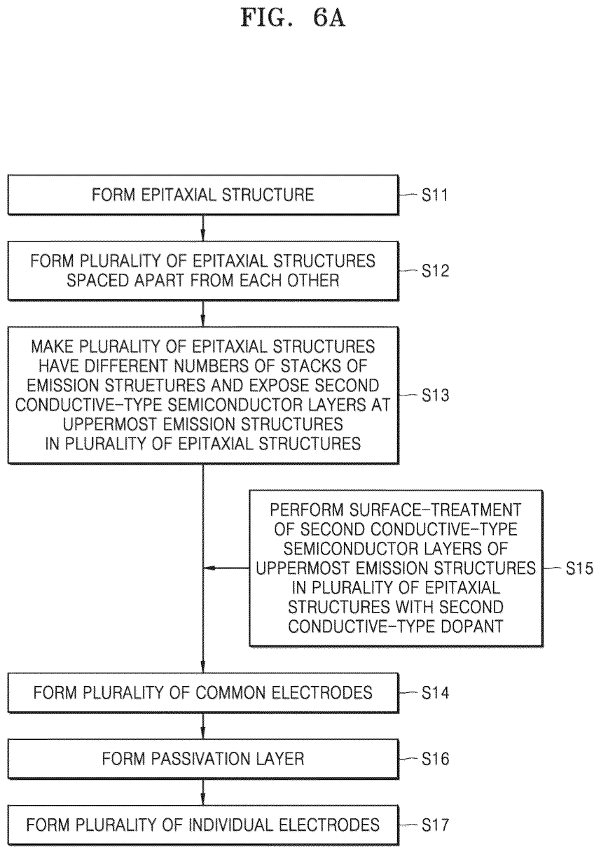

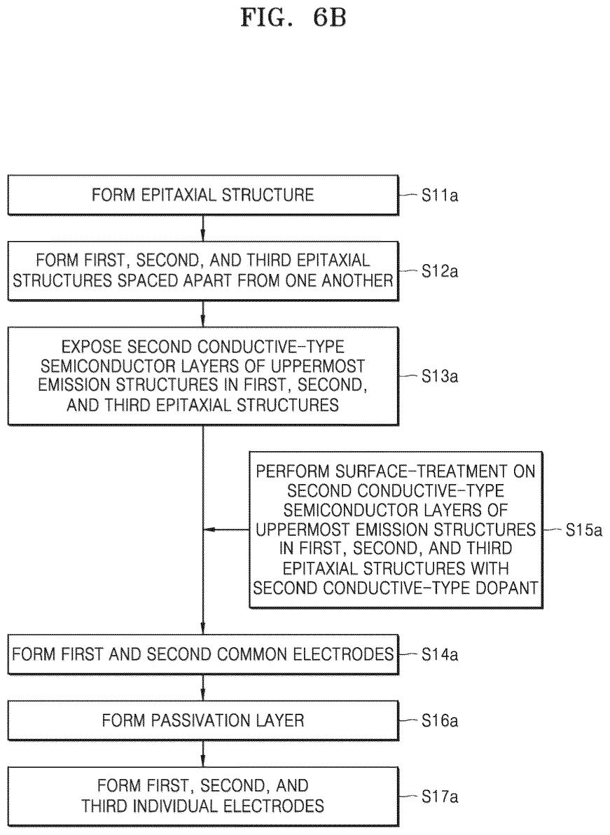

The light-emitting devices described above may be manufactured by various manufacturing methods. FIG. 6A is a flowchart illustrating a method of manufacturing a light-emitting device, according to one or more embodiments. Referring to FIG. 6A, a method of manufacturing the light-emitting device according to one or more embodiments may include forming an epitaxial structure in which a plurality of emission structures each including the first conductive semiconductor layer, the active layer, and the second conductive-type semiconductor layer that are sequentially stacked are stacked (S11), forming a plurality of epitaxial structures by etching the epitaxial structure to the first conductive-type semiconductor layer in the lowermost emission structure (S12), etching the plurality of epitaxial structures to make the plurality of epitaxial structures have different numbers of the emission structures and exposing the second conductive-type semiconductor layers in the uppermost emission structures of the plurality of epitaxial structures (S13), and forming a plurality of common electrodes which extend from the exposed surfaces of the first conductive-type semiconductor layers at the lowermost emission structures in the epitaxial structures along the side surfaces of the plurality of epitaxial structures and come into contact with the side surfaces of the first conductive-type semiconductor layers at the uppermost emission structures respectively in the plurality of epitaxial structures (S14).

The method of manufacturing the light-emitting device according to one or more embodiments may further include performing the surface treatment on the second conductive-type semiconductor layers at the uppermost emission structures in the plurality of epitaxial structures with a second conductive-type dopant (S15).

The method of manufacturing the light-emitting device according to one or more embodiments may further include forming a passivation layer that covers the plurality of epitaxial structures and has a plurality of openings exposing the second conductive-type semiconductor layers in the uppermost emission structures of the plurality of epitaxial structures (S16).

The method of manufacturing the light-emitting device according to one or more embodiments may further include forming a plurality of individual electrodes coming into contact the second conductive-type semiconductor layers in the uppermost emission structures of the plurality of epitaxial structures through the plurality of openings (S17).

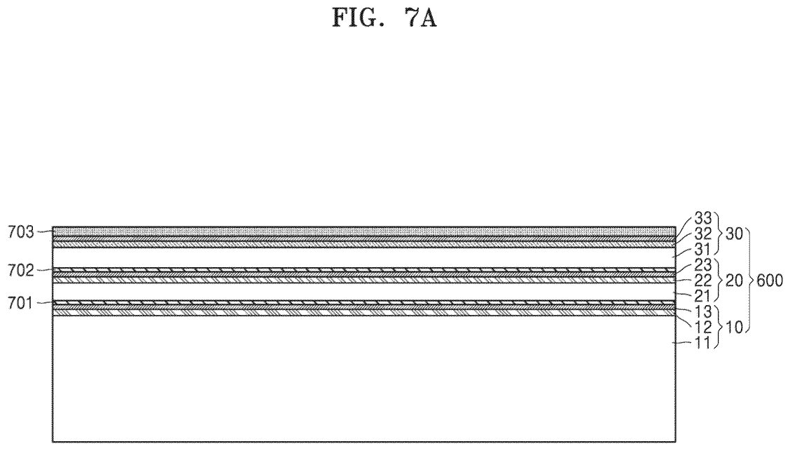

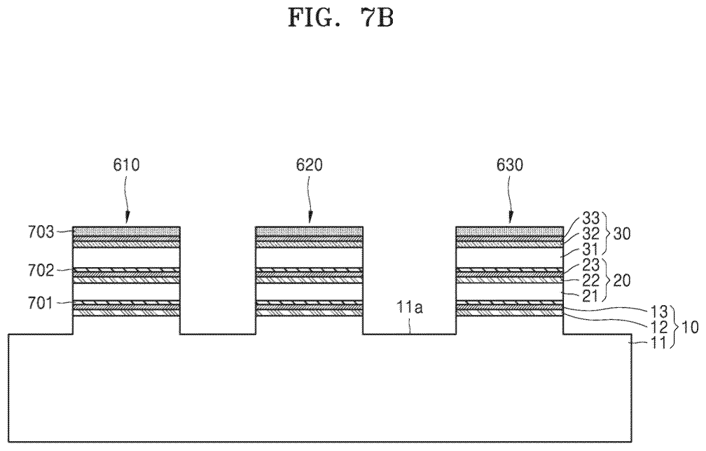

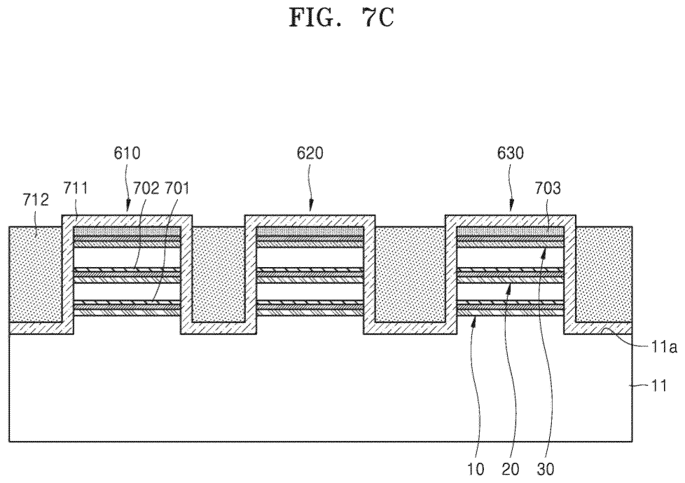

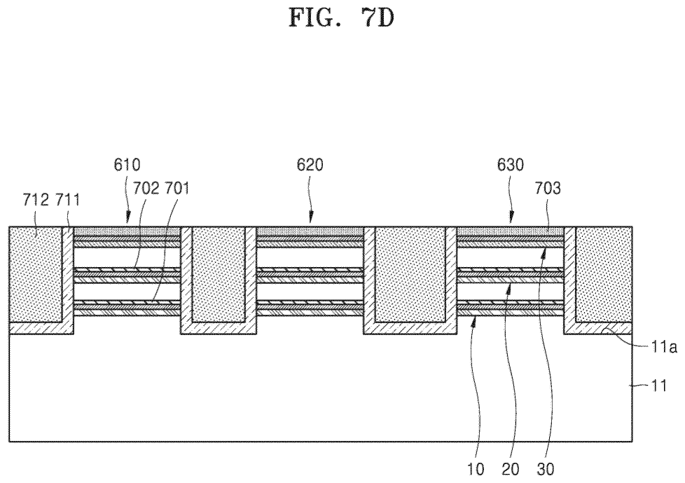

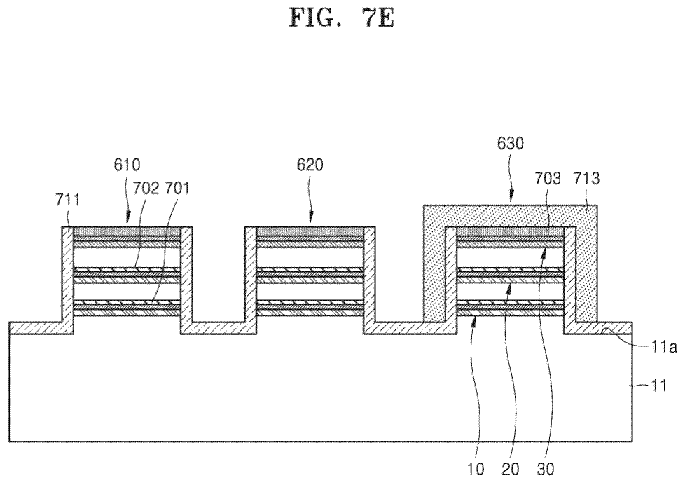

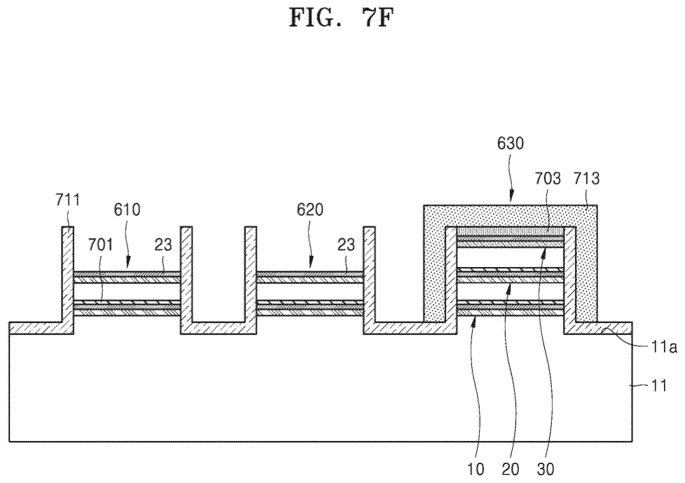

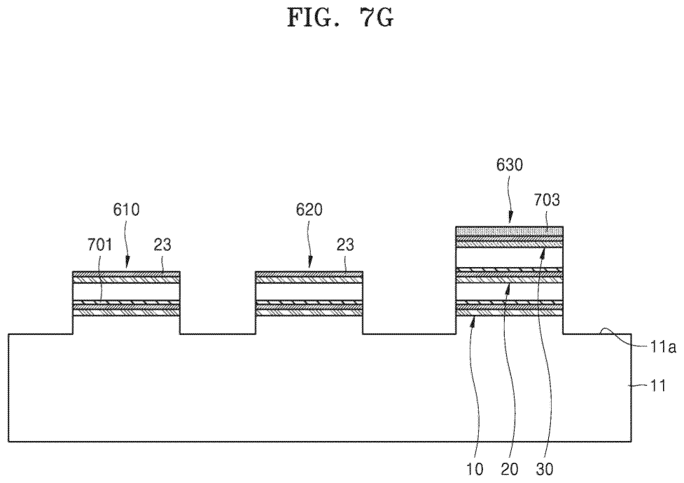

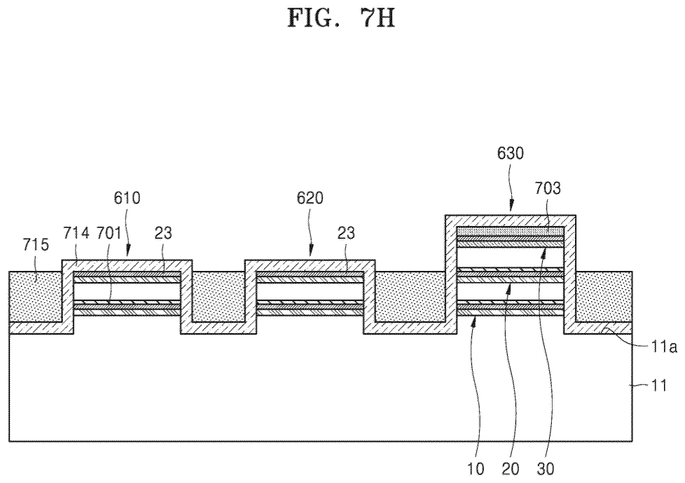

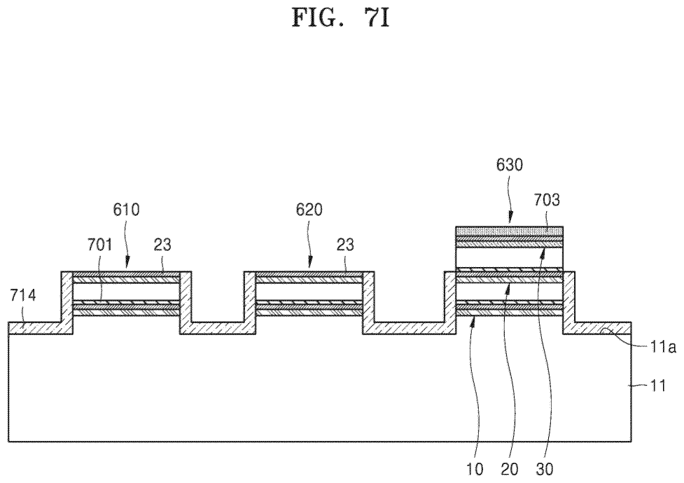

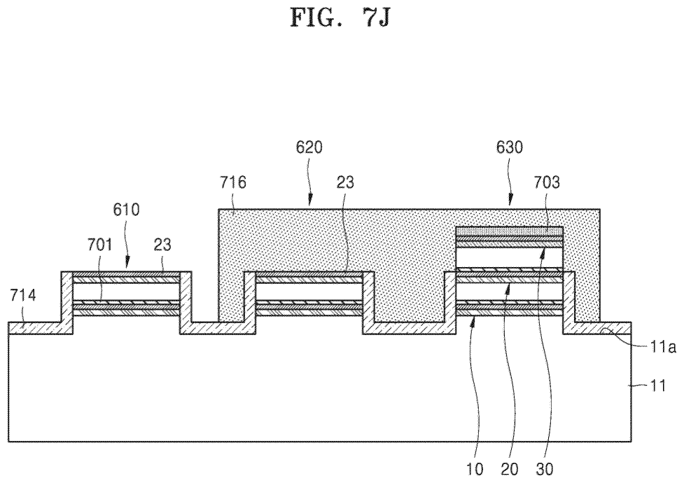

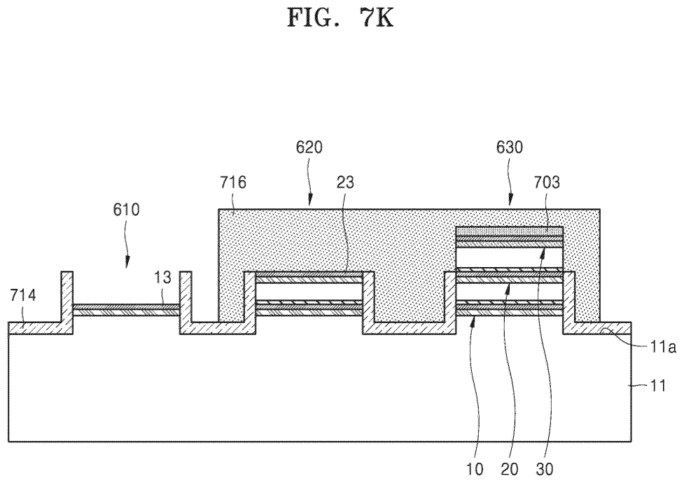

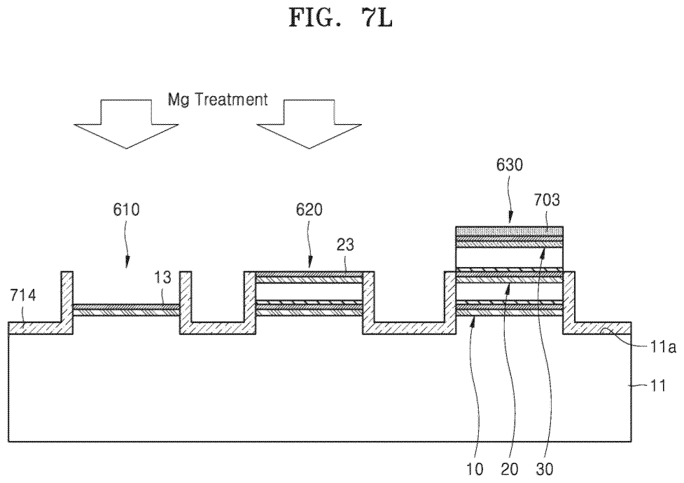

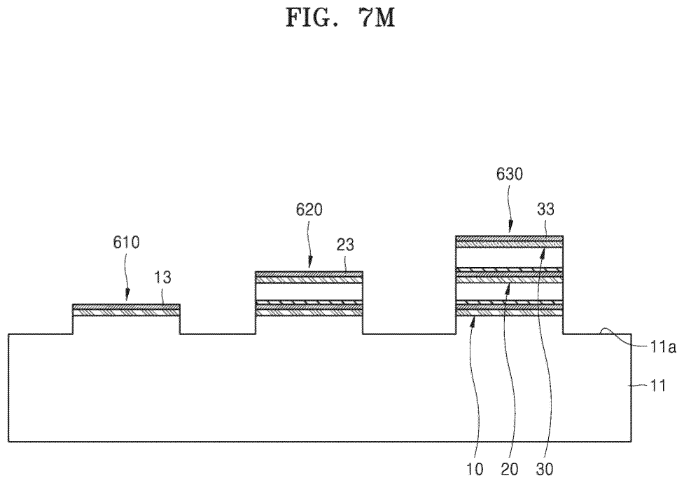

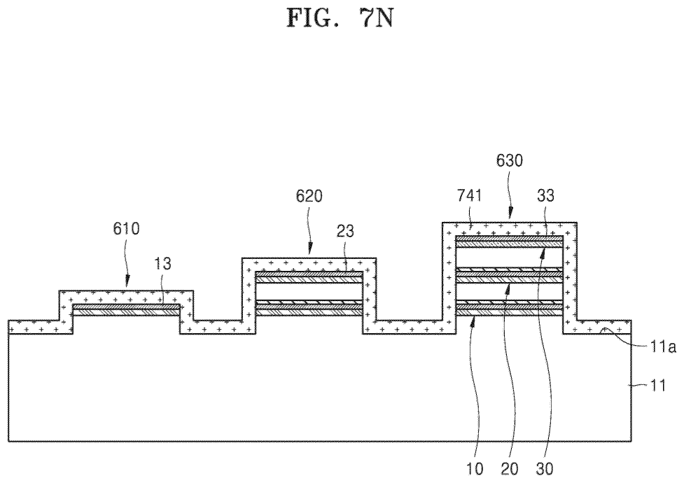

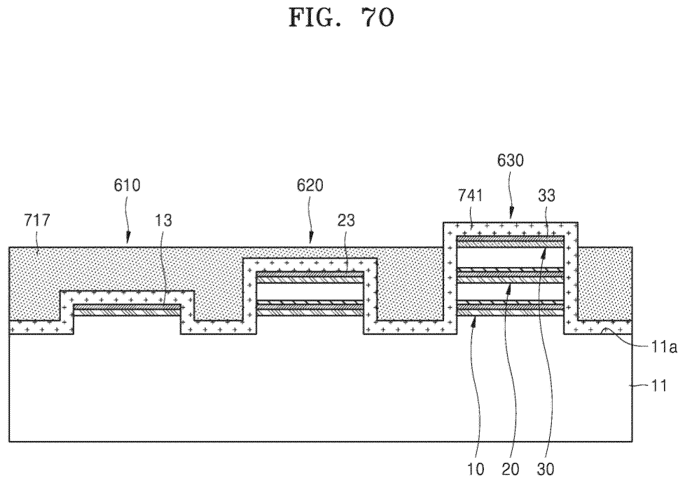

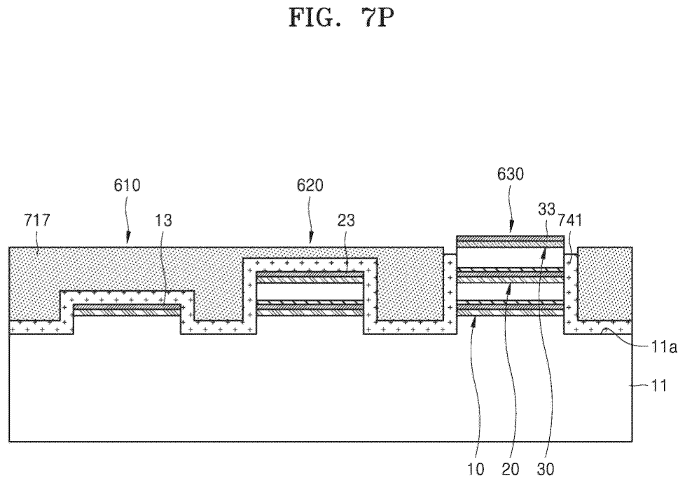

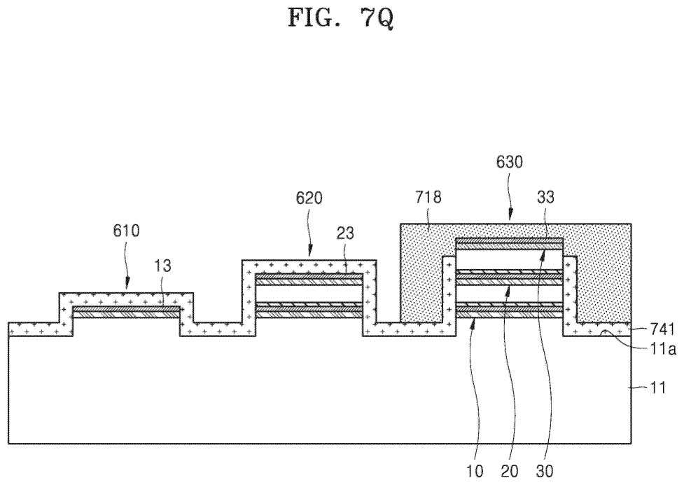

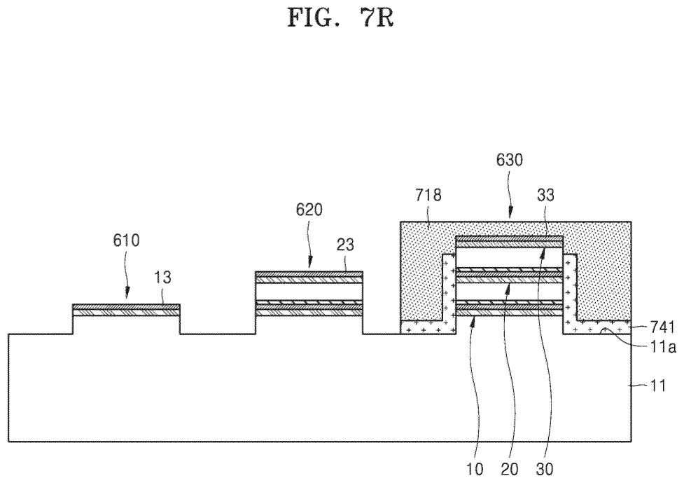

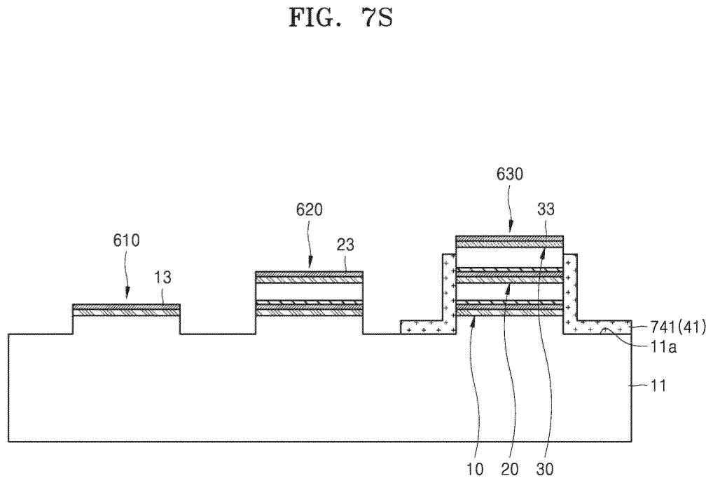

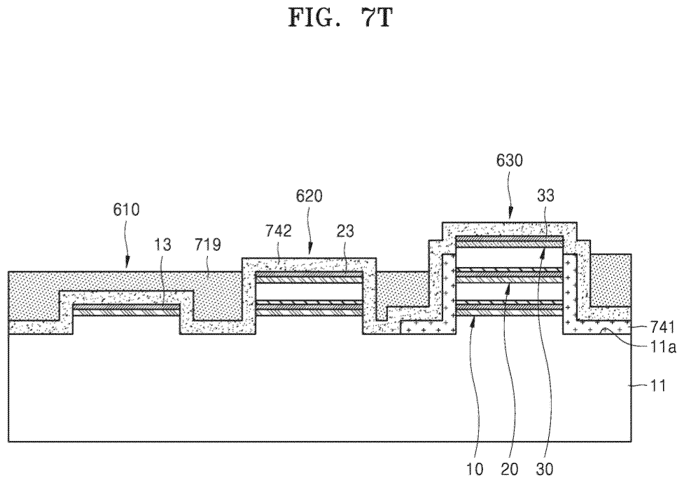

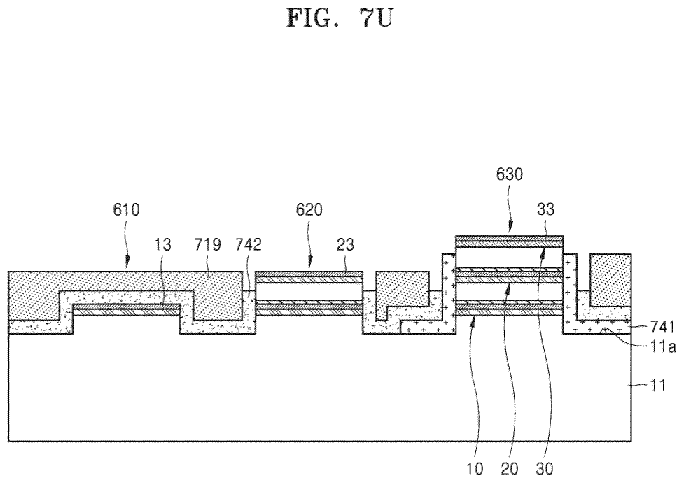

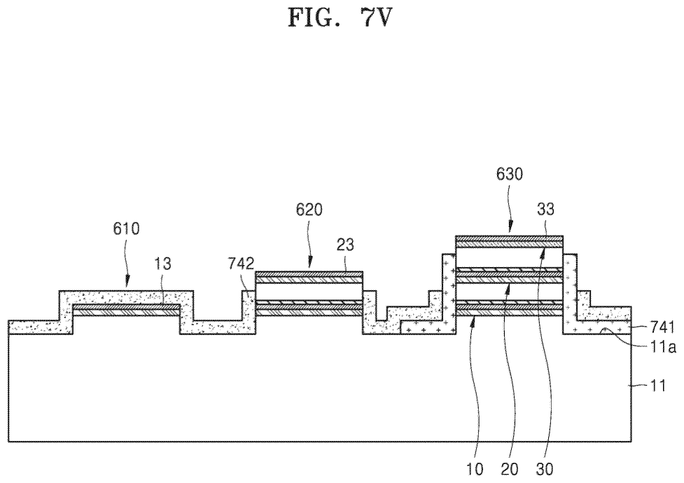

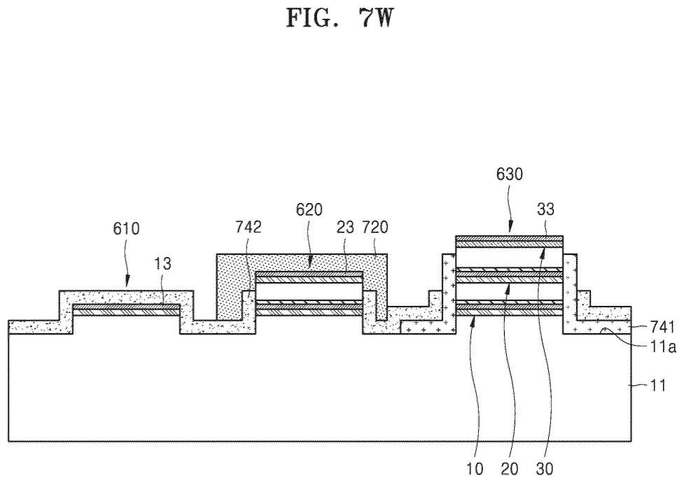

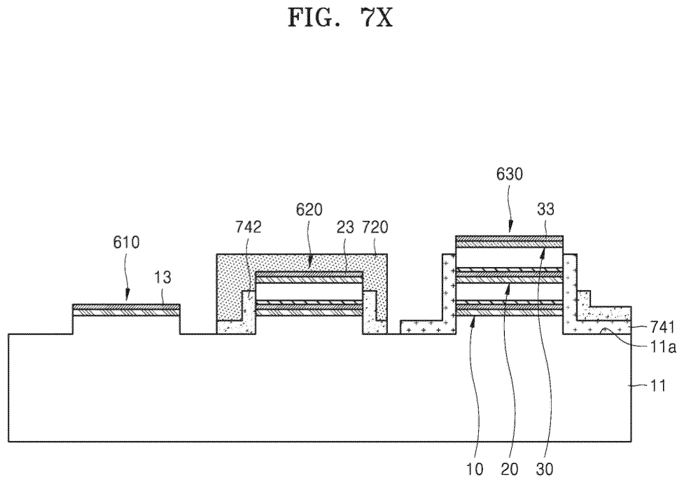

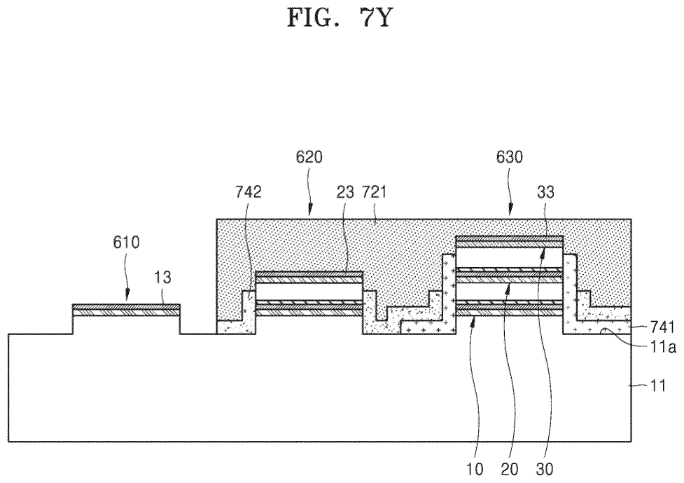

FIG. 6B is a flowchart illustrating a method of manufacturing the light-emitting device including the first, second, and third light-emitting portions 100, 200, and 300 according to one or more embodiments. FIGS. 7A to 7Y are diagrams showing the methods of manufacturing the light-emitting device including the first, second, and third light-emitting portions 100, 200, and 300, according to one or more embodiments. Hereinafter, the methods of manufacturing the light-emitting device including the first, second, and third light-emitting portions 100, 200, and 300 according to one or more embodiments are described below with reference to FIGS. 6A, 6B, and 7A to 7Y. Hereinafter, like components as the above-described components are denoted by the same reference numerals and descriptions thereof are omitted.

A process of forming the epitaxial structure having a plurality of emission structures is performed (S11). In an example, in the forming of the epitaxial structure (S11), the epitaxial structure is formed by stacking first, second, and third emission structures each including the first conductive semiconductor layer, the active layer, and the second conductive semiconductor layer that are sequentially stacked (S11a).

Referring to FIG. 7A, an epitaxial structure 600 is formed by sequentially stacking and growing the first emission structure 10, the second emission structure 20, and the third emission structure 30 on a growth substrate. The growth substrate is a substrate for growing semiconductor single-crystals, for example, may include a silicon (Si) substrate, silicon carbide (SiC) substrate, a sapphire substrate, etc. A substrate including a material that is suitable for growing the emission structure that is to be formed on the growth substrate, e.g., AlN, AlGaN, zinc oxide (ZnO), GaAs, magnesium aluminum oxide (MgAl₂O₄), magnesium oxide (MgO), lithium aluminum oxide (LiAlO₂), lithium gallium oxide (LiGaO₂), and GaN, may be used. A buffer layer that is necessary for epitaxial growth of the emission structure on the surface of the growth substrate may be provided, and the emission structure may be grown on the buffer layer.

For example, the epitaxial structure 600 may include a group III-V nitride semiconductor material. The group III-V nitride semiconductor material may include, for example, GaN, InGaN, AlInGaN, AlGaInP, etc. The epitaxial structure 600 may include a GaN-based semiconductor material. The first emission structure 10 includes the first conductive-type semiconductor layer 11, the active layer 12, and the second conductive-type semiconductor layer 13. The second emission structure 20 includes the first conductive-type semiconductor layer 21, the active layer 22, and the second conductive-type semiconductor layer 23. The third emission structure 30 includes the first conductive-type semiconductor layer 31, the active layer 32, and the second conductive-type semiconductor layer 33. In one or more embodiments, the first conductive-type semiconductor layers 11, 21, and 31 may include n-type semiconductor layers, e.g., n-GaN, and the second conductive-type semiconductor layers 13, 23, and 33 may include p-type semiconductor layers, e.g., p-GaN. According to an indium concentration in the material layer including In in the active layers 12, 22, and 32, the wavelengths of light emitted from the first, second, and third emission structures 10, 20, and 30 may vary. For example, the first, second, and third emission structures 10, 20, and 30 may respectively emit blue light (e.g., light having a wavelength range of 460±20 nm), green light (e.g., light having a wavelength range of 530±20 nm), and red light (e.g., light having a wavelength range of 630±20 nm). However, one or more embodiments are not limited thereto, and the first, second, and third emission structures 10, 20, and 30 may emit light of other wavelength bands than the blue light, green light, and red light.

In one or more embodiments, operation S11 may include forming an etch stop layer having an etching speed different from an etching speed of the material forming the plurality of emission structures between adjacent pairs of the plurality of emission structures. For example, operation S11a may include forming etch stop layers having different etching speeds than that of the materials of the first, second, and third emission structures 10, 20, and 30, e.g., GaN-based semiconductor material, between adjacent pairs of the first, second, and third emission structures 10, 20, and 30. For example, an etch stop layer 701 may be stacked on the first emission structure 10, and the second emission structure 20 may be stacked on the etch stop layer 701. Also, an etch stop layer 702 may be stacked on the second emission structure 20, and the third emission structure 30 may be stacked on the etch stop layer 702. The etch stop layers 701 and 702 may include a material having relatively slow etching speed as compared with the material forming the emission structures. For epitaxial growth, the etch stop layers 701 and 702 may include a material belonging to the same base as that of a material forming the emission structures, e.g., AlGaN.

The epitaxial structure 600 may be formed by hybrid vapor phase epitaxy (HVPE), molecular beam epitaxy (MBE), metal organic vapor phase epitaxy (MOVPE), metal organic chemical vapor deposition (MOCVD), etc., or combination thereof.

A protective layer 703 may be further formed on the epitaxial structure 600. The protective layer 703 may be formed of, for example, ITO. The protective layer 703 may prevent the second conductive-type semiconductor layer 33 of the third emission structure 30 from being damaged during an etching process, etc. described later. Also, the protective layer 703 may act as a surface treatment prevention layer during a surface treatment process on the second conductive-type semiconductor layer 33 by using an Mg dopant that is described later.

A process of forming the plurality of epitaxial structures that are spaced apart from one another is performed (S12). For example, in operation S12a, the protective layer 703 and the epitaxial structure 600 are etched to the first conductive-type semiconductor layer 11 of the first emission structure 10 so as to form a first epitaxial structure 610, a second epitaxial structure 620, and a third epitaxial structure 630 that are spaced apart from one another (S12a).

An etching mask defining regions where the first, second, and third epitaxial structures 610, 620, and 630 are to be formed is formed on the upper surface of the protective layer 703 shown in FIG. 7A, and then, the epitaxial structure 600 is mesa-etched. The etching may be performed through a wet etching process. The wet etching process may be performed by using, for example, a potassium hydroxide (KOH) solution or a tetramethyl ammonium hydroxide (TMAH) solution as an etchant. The etching may be performed from the upper surface of the first conductive-type semiconductor layer 11 of the first emission structure 10 to a certain depth. Accordingly, as shown in FIG. 7B, the first, second, and third epitaxial structures 610, 620, and 630 that are spaced apart from one another may be formed on the common first conductive-type semiconductor layer 11. The exposed surface 11a of the common first conductive-type semiconductor layer 11 may be flat.

Next, a process of etching the plurality of epitaxial structures to make the number of stacks in the emission structures different from each other and exposing the second conductive-type semiconductor layers in the uppermost emission structures of the plurality of epitaxial structures is performed (S13). For example, in operation S13, the second conductive-type semiconductor layer 13 of the first emission structure 10 in the first epitaxial structure 610, the second conductive-type semiconductor layer 23 of the second emission structure 20 in the second epitaxial structure 620, and the second conductive-type semiconductor layer 33 (the protective layer 703 in one or more embodiments) of the third emission structure 30 in the third epitaxial structure 630 may be exposed (S13a).

Operation S13a according to one or more embodiments is described with reference to FIGS. 7C to 7K and 7M. In one or more embodiments, operation S13a may include exposing the uppermost material layers (the protective layer 703 in one or more embodiments) of the first, second, and third epitaxial structures 610, 620, and 630, exposing the second conductive-type semiconductor layers 23 of the second emission structures 20 in the first and second epitaxial structures 610 and 620 by removing the third emission structures 30 of the first and second epitaxial structures 610 and 620, and exposing the second conductive-type semiconductor layer 13 of the first emission structure 10 by removing the second emission structure 20 of the first epitaxial structure 610.

As shown in FIG. 7C, a protective layer 711 covering the surfaces of the first, second, and third epitaxial structures 610, 620, and 630, the surface of the protective layer 703, and the surface 11a of the first conductive-type semiconductor layer 11 is formed. Next, an etching mask 712 that exposes the regions, in the protective layer 711, covering the protective layer 703 that is the uppermost material layer of the first, second, and third epitaxial structures 610, 620, and 630 is formed. The protective layer 711 may include a material having a less etch selectivity as compared with the semiconductor material forming the epitaxial structure 600, e.g., GaN-based semiconductor material, with respect to the etchant, e.g., the wet etchant. The protective layer 711 may include, for example, SiO₂. The etching mask 712 may include, for example, photoresist.

The regions, in the protective layer 711, covering the protective layers 703 that are the uppermost material layers of the first, second, and third epitaxial structures 610, 620, and 630 are removed by using the etching mask 712, and as shown in FIG. 7D, the protective layers 703 of the first, second, and third epitaxial structures 610, 620, and 630 are exposed. The process may be performed through, e.g., a dry etching process. The dry etching process may use, for example, inductively coupled plasma (ICP). When the protective layer 703 is not applied, the second conductive-type semiconductor layers 33 of the third emission structures 30 in the first, second, and third epitaxial structures 610, 620, and 630 are exposed through the above process.

Next, as shown in FIG. 7E, an etching mask 713 covering the third epitaxial structure 630 is formed by using, for example, photoresist. As shown in FIG. 7F, the protective layers 703 on the first and second epitaxial structures 610 and 620 and the third emission structures 30 of the first and second epitaxial structures 610 and 620 are removed by using the etching mask 713. The process may be performed through, e.g., a wet etching process. The wet etching process may be performed by using, for example, potassium hydroxide (KOH) solution or tetramethyl ammonium hydroxide (TMAH) solution as an etchant. As described above, SiO₂ included in the protective layer 711 has relatively low etch selectivity with respect to the wet etchant as compared with the GaN-based semiconductor material, and thus, the third emission structures 30 of the first and second epitaxial structures 610 and 620 are removed. Here, because the etching speed of the etch stop layer 702 between the third emission structure 30 and the second emission structure 20 is relatively lower than that of GaN, it may be prevented from excessively etching to the second conductive-type semiconductor layer 23 of the second emission structure 20 by adjusting the feeding speed of the etchant and etching time duration.

Next, the protective layer 711 and the etching mask 713 are removed. The process may be performed through, e.g., a dry etching process. Accordingly, as shown in FIG. 7G, the uppermost emission structures of the first and second epitaxial structures 610 and 620 are the second emission structure 20, and the second conductive-type semiconductor layers 23 of the first and second epitaxial structures 610 and 620 are exposed. The uppermost emission structure of the third epitaxial structure 630 is the third emission structure 30, and the second conductive-type semiconductor layer 33 of the third emission structure 30 is covered by the protective layer 703.

Next, as shown in FIG. 7H, a protective layer 714 covering the surfaces of the first, second, and third epitaxial structures 610, 620, and 630 and the surface 11a of the first conductive-type semiconductor layer 11, and the etching mask 715 exposing the regions, in the protective layer 714, covering the upper surfaces of the first and second epitaxial structures 610 and 620 and covering the third emission structure 30 of the third epitaxial structure 630, is formed. The protective layer 714 may include, for example, SiO₂. The etching mask 715 may include, for example, photoresist.

Through the dry etching process using the etching mask 715, in the protective layer 714, the part covering the upper surfaces of the first and second epitaxial structures 610 and 620 and the part covering the third emission structure 30 of the third epitaxial structure 630 are removed. Next, the etching mask 715 is removed. Then, as shown in FIG. 7I, the second conductive-type semiconductor layer 23 of the second emission structure 20 that is the uppermost layer in the first and second epitaxial structures 610 and 620.

Next, as shown in FIG. 7J, an etching mask 716 covering the second and third epitaxial structures 620 and 630 is formed by using, for example, photoresist. Through the wet etching process using the etching mask 716, as shown in FIG. 7K, the second emission structure 20 of the first epitaxial structure 610 is removed. As described above, SiO₂ included in the protective layer 714 has relatively low etch selectivity with respect to the wet etchant as compared with the GaN-based semiconductor material, and thus, the second emission structure 20 of the first epitaxial structure 610 is removed. Here, because the etching speed of the etch stop layer 701 between the second emission structure 20 and the first emission structure 10 is relatively lower than an etching speed of GaN, it may be prevented from excessively etching to the second conductive-type semiconductor layer 13 of the first emission structure 10 by adjusting the feeding speed of the etchant and etching time duration.

Next, the protective layer 714, the etching mask 716, and the protective layer 703 on the upper surface of the third epitaxial structure 630 are removed. The process may be performed through, e.g., a dry etching process. Accordingly, as shown in FIG. 7M, the uppermost emission structure in the first epitaxial structure 610 is the first emission structure 10 and the second conductive-type semiconductor layer 13 of the first emission structure 10 is exposed, the uppermost emission structure of the second epitaxial structure 620 is the second emission structure 20 and the second conductive-type semiconductor layer 23 of the second emission structure 20 is exposed, and the uppermost emission structure of the third epitaxial structure 630 is the third emission structure 30 and the second conductive-type semiconductor layer 33 of the third emission structure 30 is exposed.

The first, second, and third epitaxial structures 610, 620, and 630 formed by the above processes respectively correspond to the first, second, and third light-emitting portions 100, 200, and 300.

A surface treatment process using a second conductive-type dopant (S15) may be performed. For example, in operation S15, the surface treatment may be performed on the second conductive-type semiconductor layers 13 and 23 of the emission structures forming the uppermost layers of the first and second epitaxial structures 610 and 620 (S15a).

In the configuration shown in FIG. 7K, the protective layer 714 is removed. The process may be performed through, e.g., a dry etching process. Then, as shown in FIG. 7L, the second conductive-type semiconductor layer 13 of the first emission structure 10 in the first epitaxial structure 610 is exposed, and the second conductive-type semiconductor layer 23 of the second emission structure 20 in the second epitaxial structure 620 is exposed. In the third epitaxial structure 630, the uppermost emission structure is the third emission structure 30, and the second conductive-type semiconductor layer 33 is covered by the protective layer 703, and thus, the second conductive-type semiconductor layer 33 is not exposed. The surface treatment is performed. In one or more embodiments, the second conductive semiconductor layers 13 and 23 include p-GaN, and Mg is applied as the second conductive-type dopant for the surface treatment. In the third epitaxial structure 630, the second conductive-type semiconductor layer 33 of the third emission structure 30 is covered by the protective layer 703 and is not surface-treated, and the second conductive-type semiconductor layers 13 and 23 of the first and second epitaxial structures 610 and 620 are surface-treated. The surface dopant concentrations on the second conductive-type semiconductor layers 13 and 23 that are surface-treated may be 3×10²⁰ cm⁻³ or greater. The second conductive-type semiconductor layer 33 of the third emission structure 30 that is the uppermost emission structure in the third epitaxial structure 630 is protected by the protective layer 703 during the wet etching process, and thus the possibility of inactivating the internal p-type dopants is relatively low. However, because the second conductive-type semiconductor layers 13 and 23 of the first and second emission structures 10 and 20 that are the uppermost emission structures in the first and second epitaxial structures 610 and 620 are exposed during the wet etching process, the internal p-type dopants may be inactivated. Through the surface treatment process, degradation in a carrier feeding performance caused due to damage to the second conductive-type semiconductor layers 13 and 23 in the etching process, e.g., partial inactivation of the dopants, and the degradation in light extraction efficiency caused therefrom may be restrained.

Next, when the protective layer 714 is removed, a configuration shown in FIG. 7M is obtained.

Next, an operation of forming a plurality of common electrodes that extend from the exposed surface of the first conductive-type semiconductor layer in the lowermost emission structure along the side surface of each of the plurality of epitaxial structures to be connected to the first conductive-type semiconductor layer of the uppermost emission structure is performed (S14). For example, in operation S14, the common electrodes respectively extending from the exposed surface of the first conductive-type semiconductor layer in the first emission structure along the side surfaces of the third and second epitaxial structures to come into contact with the side surfaces of the first conductive-type semiconductor layers in the uppermost emission structures of the third and second epitaxial structures may be formed (S14a).

Operation S14a according to one or more embodiments is described below with reference to FIGS. 7N to 7Y. In one or more embodiments, operation S14a may include forming a first common electrode 41 that extends from the exposed surface 11a of the first conductive-type semiconductor layer 11 in the first emission structure 10 and comes into contact with the side surface of the first conductive-type semiconductor layer 31 of the third emission structure in the third epitaxial structure 630, and forming a second common electrode 42 that extends from the exposed surface 11a of the first conductive-type semiconductor layer 11 in the first emission structure 10 and comes into contact with the side surface of the first conductive-type semiconductor layer 21 of the second emission structure 20 in the second epitaxial structure 620.First, the process of forming the first common electrode 41 is described with reference to FIGS. 7N to 7S. The forming of the first common electrode 41 may include forming a first electrode material layer 741 by depositing a first electrode material on the first, second, and third epitaxial structures 610, 620, and 630 and the exposed surface 11a of the first conductive-type semiconductor layer 11 in the first emission structure 10, and removing the first electrode material that covers the upper surfaces of the first epitaxial structure 610, the second epitaxial structure 620, and the third epitaxial structure 630 by using a first etchant having an etch selectivity with respect to the first electrode material.

As shown in FIG. 7N, a first electrode material layer 741 is formed by depositing a first electrode material on the first, second, and third epitaxial structures 610, 620, and 630 and the exposed surface 11a of the first conductive-type semiconductor layer 11 in the first emission structure 10. This process may be performed by, for example, sputtering, atomic layer deposition (ALD), plasma enhanced atomic layer deposition (PEALD), chemical vapor deposition (CVD), plasma enhanced chemical vapor deposition (PECVD), physical vapor deposition (PVD), etc., or combinations thereof. The first electrode material may include, for example, Al, Ti, Pt, Ag, Au, Pd, TiW, ITO, Mo, or various combinations thereof. The first electrode material may be different from a second electrode material that is described later. The first electrode material and the second electrode material may have etch selectivity with respect to different etchants. For example, one of the first and second electrode materials may include ITO, and the other of the first and second electrode materials may include Mo. The ITO may have etch selectivity with respect to a HCl-based etchant, e.g., product name LCE 12. Mo has an etch selectivity with respect to a perchloric acid-based etchant, e.g., product name CR-7. The combination of the first electrode material and the second electrode material is not limited thereto, and various combinations of the electrode materials having the etch selectivity with respect to different etchants may be used. In one or more embodiments, the first electrode material may include ITO.

As shown in FIG. 7O, an etching mask 717 exposing a part, in the first electrode material layer 741, covering the upper surface of the third epitaxial structure 630. Through an etching process using a first etchant (HCl-based etchant, e.g., product name LCE12), the part covering the third epitaxial structure 630, in the first electrode material layer 741, is removed. As shown in FIG. 7P, the etching may be performed until the side surface of the first conductive-type semiconductor layer 31 of the third emission structure 30 in the third epitaxial structure 630 is partially removed over the etching mask 717. As shown in FIG. 7Q, an etching mask 718 that covers the third epitaxial structure 630, and the first electrode material layer 741 formed on the side surface of the third epitaxial structure 630 and the surface 11a of the first conductive-type semiconductor layer 11 around the third epitaxial structure 630 is formed. As shown in FIG. 7R, due to the etching process using the first etchant (HCl-based etchant, e.g., product name LCE12), the first electrode material layer 741 is removed except the part covered by the etching mask 718. Next, the etching mask 718 is removed, and then, the first common electrode 41 extending from the surface 11a of the first conductive-type semiconductor layer 11 and coming into contact with the side surface of the first conductive-type semiconductor layer 31 of the third emission structure 30 in the third epitaxial structure 630 may be formed by the remaining part of the first electrode material layer 741 as shown in FIG. 7S.

Next, processes of forming the second common electrode 42 are described with reference to FIGS. 7T to 7Y. The operation of forming the second common electrode 42 may include forming a second electrode material layer 742 by depositing a second electrode material on the first, second, and third epitaxial structures 610, 620, and 630, the first common electrode 41, and the exposed surface 11a of the first conductive-type semiconductor layer 11 in the first emission structure 10, and removing, in the second electrode material, the parts covering the first epitaxial structure 610, the upper surface of the second epitaxial structure 620, and the third epitaxial structure 630 and at least a portion of a part covering the first common electrode 41 by using a second etchant having an etch selectivity with respect to the second electrode material.

As shown in FIG. 7T, a second electrode material layer 742 is formed by depositing a second electrode material on the first, second, and third epitaxial structures 610, 620, and 630, the first electrode material layer 741, and the exposed surface 11a of the first conductive-type semiconductor layer 11 in the first emission structure 10. This process may be performed by, for example, sputtering, atomic layer deposition (ALD), plasma enhanced atomic layer deposition (PEALD), chemical vapor deposition (CVD), plasma enhanced chemical vapor deposition (PECVD), physical vapor deposition (PVD), etc., or combinations thereof. An etching mask 719 exposing a part, in the second electrode material layer 742, covering the upper surfaces of the second epitaxial structure 620 and the third epitaxial structure 630 is formed on the second electrode material layer 742.

For example, the second electrode material may include, for example, Al, Ti, Pt, Ag, Au, Pd, TiW, ITO, Mo, or various combinations thereof. As described above, the second electrode material may be different from the first electrode material. The first electrode material and the second electrode material may have etch selectivity with respect to different etchants. For example, one of the first and second electrode materials may include ITO, and the other of the first and second electrode materials may include Mo. The ITO may have etch selectivity with respect to a HCl-based etchant, e.g., product name LCE 12. Mo has an etch selectivity with respect to a perchloric acid-based etchant, e.g., product name CR-7. The combination of the first electrode material and the second electrode material is not limited thereto, and various combinations of the electrode materials having the etch selectivity with respect to different etchants may be used. In one or more embodiments, the second electrode material may include Mo.

Through the etching process using a second etchant (perchloric acid-based etchant, e.g., product name CR-7), as shown in FIG. 7U, in the second electrode material layer 742, the regions covering the upper surface of the second epitaxial structure 620 and the upper surface of the third epitaxial structure 630, and a portion of a part covering the first electrode material layer 741 are removed. The etching may be performed until the side surface of the first conductive-type semiconductor layer 21 of the second emission structure 20 in the second epitaxial structure 620 is partially exposed over the etching mask 719. As shown in FIG. 7V, the etching mask 719 is removed. As shown in FIG. 7W, an etching mask 720 that covers the second epitaxial structure 620, and the second electrode material layer 742 formed on the side surface of the second epitaxial structure 620 and the surface 11a of the first conductive-type semiconductor layer 11 around the second epitaxial structure 620 is formed. As shown in FIG. 7X, due to the etching process using the second etchant (perchloric acid-based etchant, e.g., product name CR-7), the second electrode material layer 742 is removed except the portion covered by the etching mask 720. Next, when the etching mask 720 is removed, due to the remaining part of the second electrode material layer 742, the second common electrode 42 that extends from the surface 11a of the first conductive-type semiconductor layer 11 and comes into contact with the side surface of the first conductive-type semiconductor layer 21 of the second emission structure 20 in the second epitaxial structure 620 and is spaced apart from the first common electrode 41 may be formed as shown in FIG. 1B.

In the configuration shown in FIG. 7V, an etching mask 721 covering the second and third epitaxial structures 620 and 630 and exposing the first epitaxial structure 610 is formed as shown in FIG. 7Y, and the exposed part of the second electrode material layer 742 may be removed. Due to the remaining part of the second electrode material layer 742, the second common electrode 42 that extends from the surface 11a of the first conductive-type semiconductor layer 11 and comes into contact with the side surface of the first conductive-type semiconductor layer 21 of the second emission structure 20 in the second epitaxial structure 620, and partially overlaps the first common electrode 41 may be formed as shown in FIG. 2.

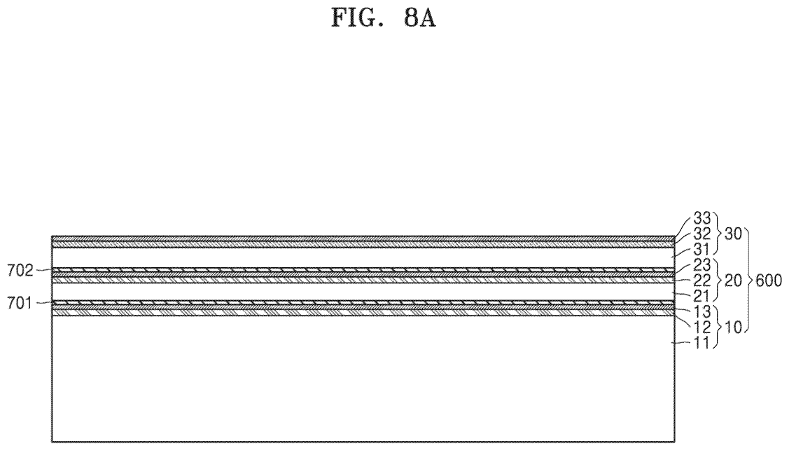

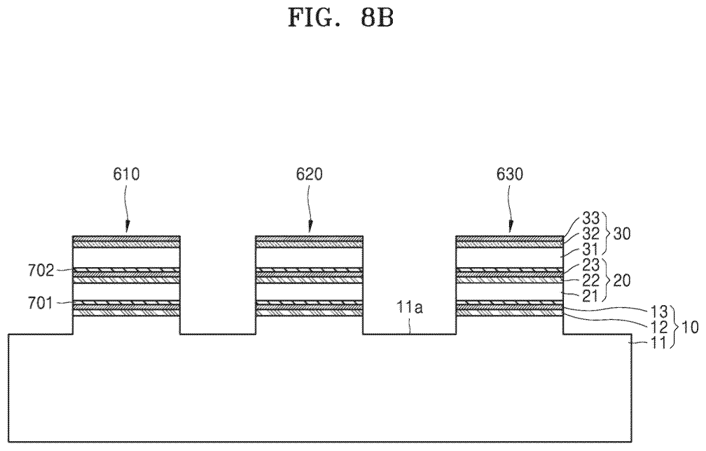

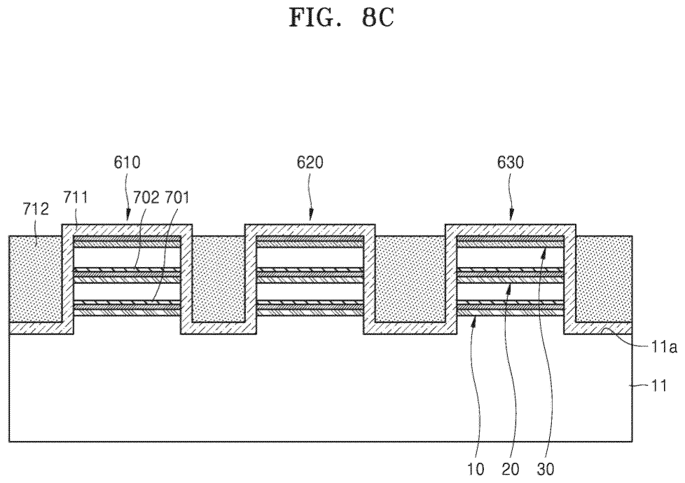

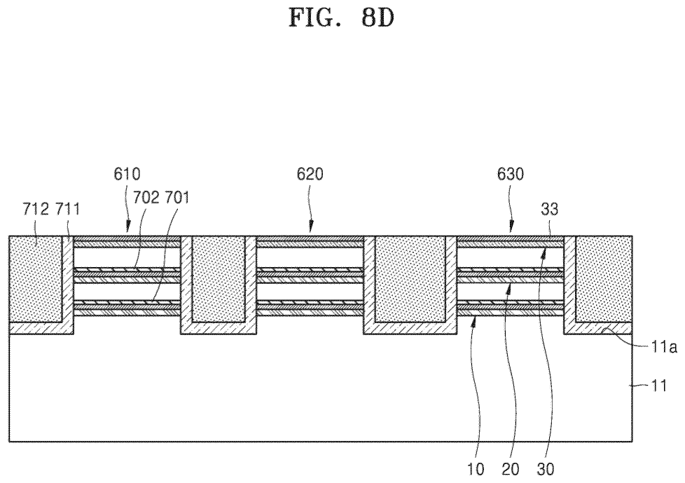

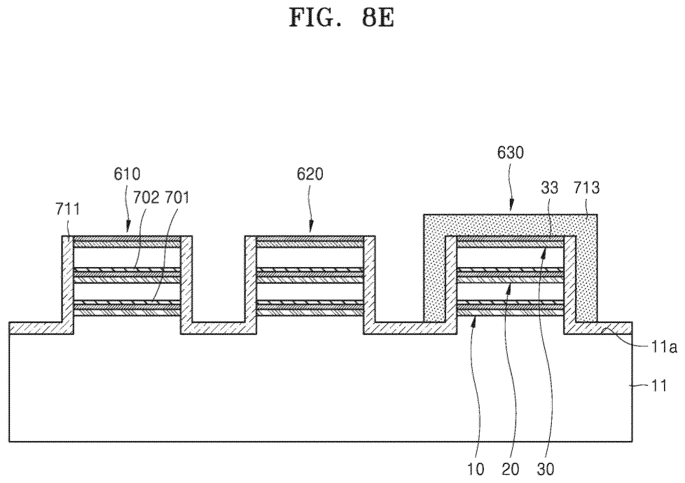

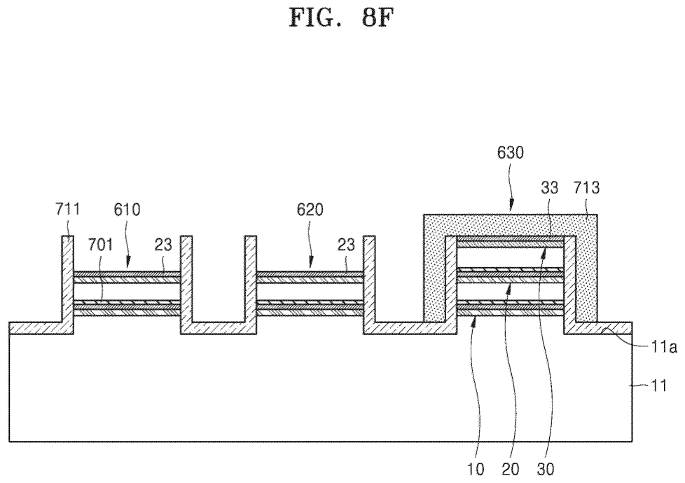

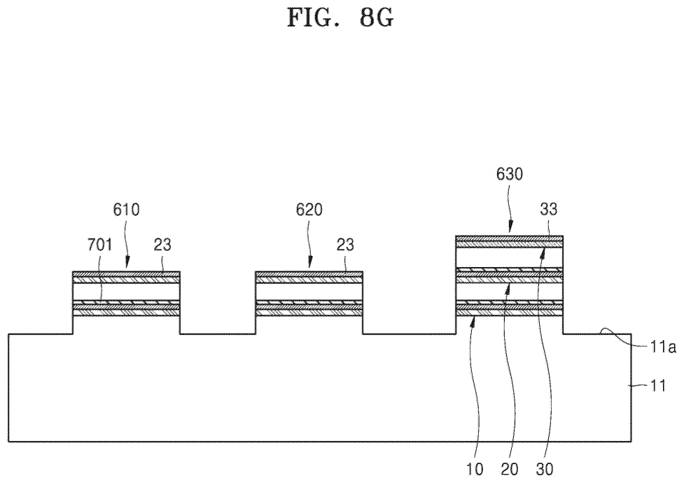

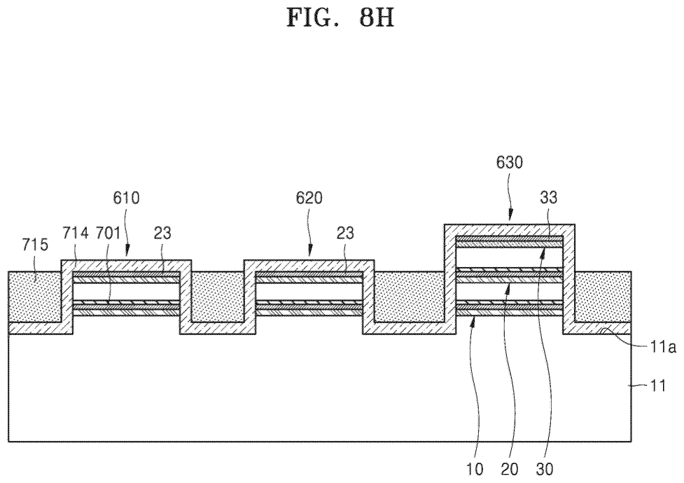

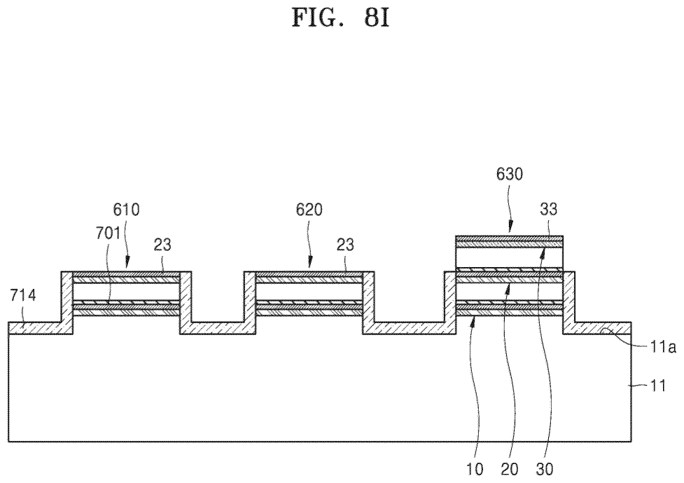

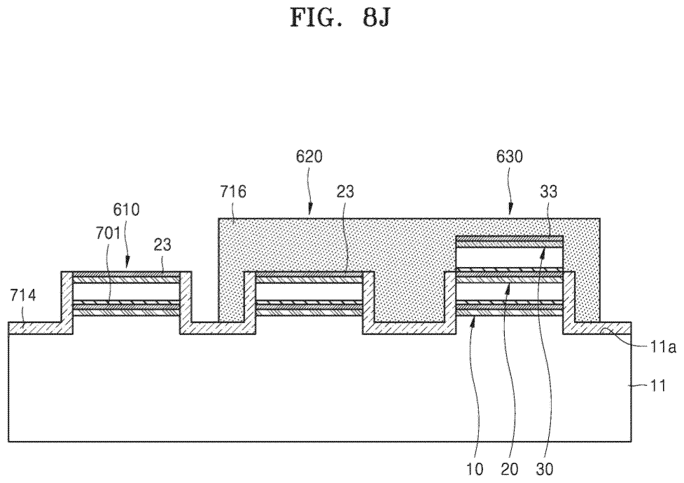

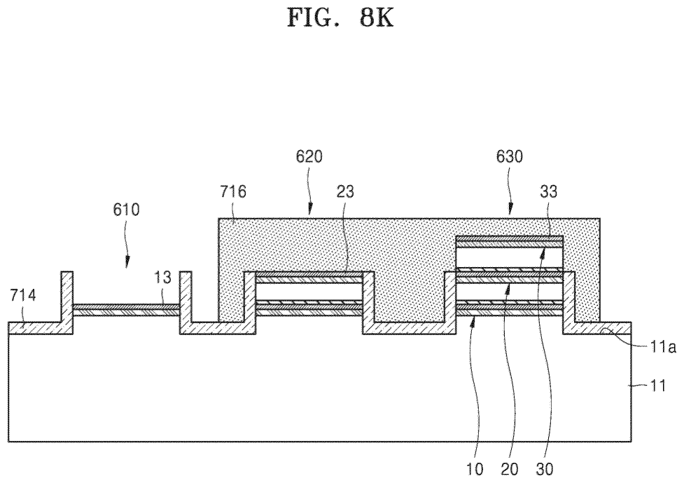

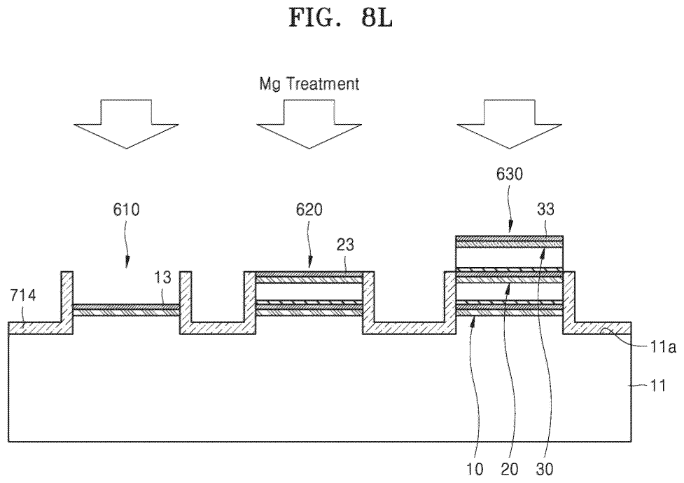

In the above embodiment, the second conductive-type semiconductor layers 13 and 23 of the first and second epitaxial structures 610 and 620 are surface-treated by the second conductive-type dopant, but the second conductive-type semiconductor layers 13, 23, and 33 of the first, second, and third epitaxial structures 610, 620, and 630 may be surface-treated by the second conductive-type dopant. FIGS. 8A to 8L are diagrams illustrating methods of manufacturing the light-emitting device, according to one or more embodiments. Hereinafter, for example, methods of manufacturing the light-emitting device including the first, second, and third light-emitting portions 100, 200, and 300 according to one or more embodiments are described. Because FIGS. 8A to 8L correspond to FIGS. 7A to 7L, descriptions about FIGS. 7A to 7L are also applied to FIGS. 8A to 8L. However, the manufacturing method according to one or more embodiments illustrated in FIGS. 8A to 8L is different from the manufacturing method according to one or more embodiments illustrated in FIGS. 7A to 7L, in that the protective layer 703 is not applied. Hereinafter, differences are described below, and like components as the above-described components are denoted by the same reference numerals and descriptions thereof are omitted.

A process of forming an epitaxial structure is performed (S11). In an example, in the forming of the epitaxial structure (S11), the epitaxial structure is formed by stacking first, second, and third emission structures each including the first conductive semiconductor layer, the active layer, and the second conductive semiconductor layer sequentially stacked (S11a).

Referring to FIG. 8A, the epitaxial structure 600 is formed by sequentially stacking and growing the first emission structure 10, the second emission structure 20, and the third emission structure 30 on a growth substrate. For example, the epitaxial structure 600 may include a group III-V nitride semiconductor material, e.g., GaN-based semiconductor material. In one or more embodiments, the first conductive-type semiconductor layers 11, 21, and 31 may include n-type semiconductor layers, e.g., n-GaN, and the second conductive-type semiconductor layers 13, 23, and 33 may include p-type semiconductor layers, e.g., p-GaN. For example, the first, second, and third emission structures 10, 20, and 30 may respectively emit blue light (e.g., light having a wavelength range of 460±20 nm), green light (e.g., light having a wavelength range of 530±20 nm), and red light (e.g., light having a wavelength range of 630±20 nm). However, embodiments are not limited thereto, and the first, second, and third emission structures 10, 20, and 30 may emit light of other wavelength bands than the blue light, green light, and red light. An etch stop layer 701 may be stacked on the first emission structure 10, and the second emission structure 20 may be stacked on the etch stop layer 701. Also, an etch stop layer 702 may be stacked on the second emission structure 20, and the third emission structure 30 may be stacked on the etch stop layer 702.

A process of forming the plurality of epitaxial structures that are spaced apart from one another is performed (S12). For example, in operation S12, the epitaxial structures 600 are etched to the first conductive-type semiconductor layer 11 of the first emission structure 10 so as to form first, second, and third epitaxial structures 610, 620, and 630 (S12a).

An etching mask defining regions where the first, second, and third epitaxial structures 610, 620, and 630 are to be formed is formed on the upper surface of the epitaxial structure 600 shown in FIG. 8A, and then, the epitaxial structure 600 is mesa-etched. The etching may be performed from the upper surface of the first conductive-type semiconductor layer 11 of the first emission structure 10 to a certain depth. Accordingly, as shown in FIG. 8B, the first, second, and third epitaxial structures 610, 620, and 630 that are spaced apart from one another may be formed on the common first conductive-type semiconductor layer 11. The exposed surface 11a of the common first conductive-type semiconductor layer 11 may be flat.

Next, operation of etching the plurality of epitaxial structures to make the number of stacks in the emission structures different from each other and exposing the second conductive-type semiconductor layers in the uppermost emission structures of the plurality of epitaxial structures is performed (S13). For example, in operation S13, the second conductive-type semiconductor layer 13 of the first emission structure 10 in the first epitaxial structure 610, the second conductive-type semiconductor layer 23 of the second emission structure 20 in the second epitaxial structure 620, and the second conductive-type semiconductor layer 33 of the third emission structure 30 in the third epitaxial structure 630 may be exposed (S13a).

Operation S13a according to one or more embodiments is described with reference to FIGS. 8C to 8K. In one or more embodiments, operation S13 may include exposing the second conductive-type semiconductor layers 33 of the third emission structures 30 in the first, second, and third epitaxial structures 610, 620, and 630, exposing the second conductive-type semiconductor layers 23 of the second emission structures 20 in the first and second epitaxial structures 610 and 620 by removing the third emission structures 30 of the first and second epitaxial structures 610 and 620, and exposing the second conductive-type semiconductor layer 13 of the first emission structure 10 by removing the second emission structure 20 of the first epitaxial structure 610.

As shown in FIG. 8C, a protective layer 711 covering the surfaces of the first, second, and third epitaxial structures 610, 620, and 630, and the surface 11a of the first conductive-type semiconductor layer 11 is formed. Next, an etching mask 712 that exposes the regions, in the protective layer 711, covering the upper surfaces of the first, second, and third epitaxial structures 610, 620, and 630 is formed. The regions, in the protective layer 711, covering the upper surfaces of the first, second, and third epitaxial structures 610, 620, and 630 are removed by using the etching mask 712, and as shown in FIG. 8D, the second conductive-type semiconductor layers 33 of the first, second, and third epitaxial structures 610, 620, and 630 are exposed.

Next, as shown in FIG. 8E, an etching mask 713 covering the third epitaxial structure 630 is formed by using, for example, photoresist. The third emission structures 30 of the first and second epitaxial structures 610 and 620 are removed by using the etching mask 713 as shown in FIG. 8F. The etch stop layer 702 between the third emission structure 30 and the second emission structure 20 may prevent the etching from progressing excessively to the second conductive-type semiconductor layer 23 of the second emission structure 20.

Next, when the protective layer 711 and the etching mask 713 are removed, as shown in FIG. 8G, the uppermost emission structure of the first and second epitaxial structures 610 and 620 is the second emission structure 20, and the second conductive-type semiconductor layer 23 is exposed.

Next, as shown in FIG. 8H, the protective layer 714 covering the surfaces of the first, second, and third epitaxial structures 610, 620, and 630, and the surface 11a of the first conductive-type semiconductor layer 11 is formed. The etching mask 715 exposing the parts, in the protective layer 714, covering the upper surfaces of the first and second epitaxial structures 610 and 620 and covering the third emission structure 30 of the third epitaxial structure 630 is formed. In the protective layer 714, the part covering the upper surfaces of the first and second epitaxial structures 610 and 620 and the part covering the third emission structure 30 of the third epitaxial structure 630 are removed by using the etching mask 715 and the etching mask 715 is removed. Then, as shown in FIG. 8I, the second conductive-type semiconductor layer 23 of the second emission structure 20 that is the uppermost layer in the first and second epitaxial structures 610 and 620.

Next, as shown in FIG. 8J, the etching mask 716 covering the second and third epitaxial structures 620 and 630 is formed by using, for example, photoresist. The second emission structure 20 of the first epitaxial structure 610 is removed by using the etching mask 716, as shown in FIG. 8K. The etch stop layer 701 between the second emission structure 20 and the first emission structure 10 may prevent the etching from progressing excessively to the second conductive-type semiconductor layer 13 of the first emission structure 10.

The first, second, and third epitaxial structures 610, 620, and 630 formed by the above processes respectively correspond to the first, second, and third light-emitting portions 100, 200, and 300.

A surface treatment process using a second conductive-type dopant (S15) may be performed. For example, in operation S15, the surface treatment may be performed at least on the second conductive-type semiconductor layers 13, 23, and 33 of the emission structures forming the uppermost layers of the first, second, and third epitaxial structures 610, 620, and 630 (S15a).

In the configuration shown in FIG. 8K, the etching mask 716 is removed. Then, as shown in FIG. 8L, the second conductive-type semiconductor layers 13, 23, and 33 of the first, second, and third epitaxial structures 610, 620, and 630 are exposed. In this configuration, the surface treatment is performed. In one or more embodiments, the second conductive semiconductor layers 13, 23, and 33 may include p-GaN, and Mg is applied as the second conductive-type dopant for the surface treatment. The surface dopant concentrations on the second conductive-type semiconductor layers 13, 23, and 33 that are surface-treated may be 3×10²⁰ cm⁻³ or greater. Through the surface treatment process, degradation in a carrier feeding performance caused due to damage to the second conductive-type semiconductor layers 13, 23, and 33 in the etching process, e.g., partial inactivation of the dopants, and the degradation in light extraction efficiency caused therefrom may be restrained.

Then, when the protective layer 714 is removed, the uppermost emission structure in the first epitaxial structure 610 is the first emission structure 10 and the second conductive-type semiconductor layer 13 is exposed, the uppermost emission structure of the second epitaxial structure 620 is the second emission structure 20 and the second conductive-type semiconductor layer 23 is exposed, and the uppermost emission structure of the third epitaxial structure 630 is the third emission structure 30 and the second conductive-type semiconductor layer 33 may be exposed.

The processes shown in FIGS. 7N to 7Y are performed, and thus the common electrodes and individual electrodes may be formed.

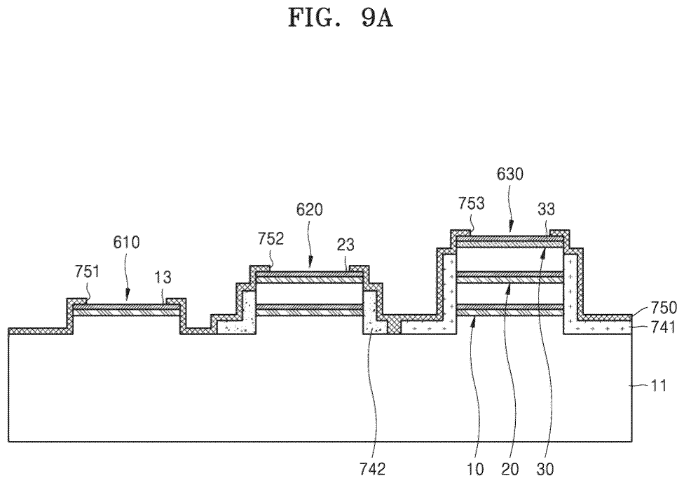

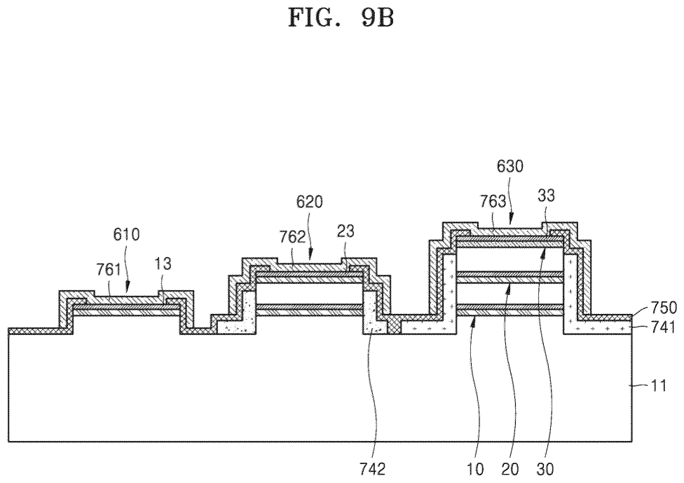

A process of forming a passivation layer that covers a plurality of epitaxial structures and includes a plurality of openings exposing the second conductive-type semiconductor layers of the uppermost emission structures in the plurality of epitaxial structures is performed (S16). For example, in operation S16, a passivation layer 750 having a plurality of openings 751, 752, and 753 exposing the second conductive-type semiconductor layers 13, 23, and 33 of the uppermost emission structures 10, 20, and 30 in the first, second, and third epitaxial structures 610, 620, and 630 may be formed (S16a). FIG. 9A is a diagram showing the passivation layer 750 being formed. Referring to FIG. 9A, operation 16a according to one or more embodiments is described.

For example, in the configuration shown in FIG. 7Y, the passivation layer 750 may be formed on the first, second, and third epitaxial structures 610, 620, and 630 and the first and second electrode material layers 741 and 742, and then, openings 751, 752, and 753 respectively exposing the upper surfaces of the second conductive-type semiconductor layers 13, 23, and 33 at the uppermost layers of the first, second, and third epitaxial structures 610, 620, and 630 may be formed by patterning the passivation layer 750. The passivation layer 750 may include a charge blocking layer for preventing charge diffusion through the side surfaces of the first, second, and third epitaxial structures 610, 620, and 630. The charge blocking layer may have, for example, a single-layered structure including AlN or a multi-layered structure including AlN/AlOₓ. The passivation layer 750 may further include a reflective layer arranged outside the charge blocking layer. The reflective layer may have, for example, a DBR structure. The DBR structure may have a structure, for example, of stacking SiO₂/TiO₂ three times.

An operation of forming a plurality of individual electrodes coming into contact with the second conductive-type semiconductor layers of the uppermost emission structures in the plurality of epitaxial structures through the plurality of openings is performed (S17). For example, in operation S17, a plurality of individual electrodes 761, 762, and 763 coming into contact with the second conductive-type semiconductor layers 13, 23, and 33 of the uppermost emission structures 10, 20, and 30 in the plurality of epitaxial structures 610, 620, and 630 through the plurality of openings 751, 752, and 753 may be formed (S17a). FIG. 9B is a diagram showing individual electrodes being formed. Referring to FIG. 9B, operation 17a according to one or more embodiments is described.

For example, in the configuration shown in FIG. 9A, an electrode material layer may be formed by depositing an electrode material on the surface of the passivation layer 750 and on the upper surfaces of the second conductive semiconductor layers 13, 23, and 33 at the uppermost layers of the first, second, and third epitaxial structures 610, 620, and 630, which are exposed through the openings 751, 752, and 753. The electrode material may include, for example, Al, Ti, Pt, Ag, Au, Pd, TiW, or various combinations thereof. The electrode material may include a transparent electrode material, e.g., ITO. This process may be performed by, for example, sputtering, atomic layer deposition (ALD), plasma enhanced atomic layer deposition (PEALD), chemical vapor deposition (CVD), plasma enhanced chemical vapor deposition (PECVD), physical vapor deposition (PVD), etc., or combinations thereof. Then, the first, second, and third individual electrodes 761, 762, and 763 respectively coming into contact with the upper surfaces of the second conductive-type semiconductor layers 13, 23, and 33 at the uppermost layers of the first, second, and third epitaxial structures 610, 620, and 630, which are exposed through the openings 751, 752, and 753, may be formed by patterning the electrode material layer.

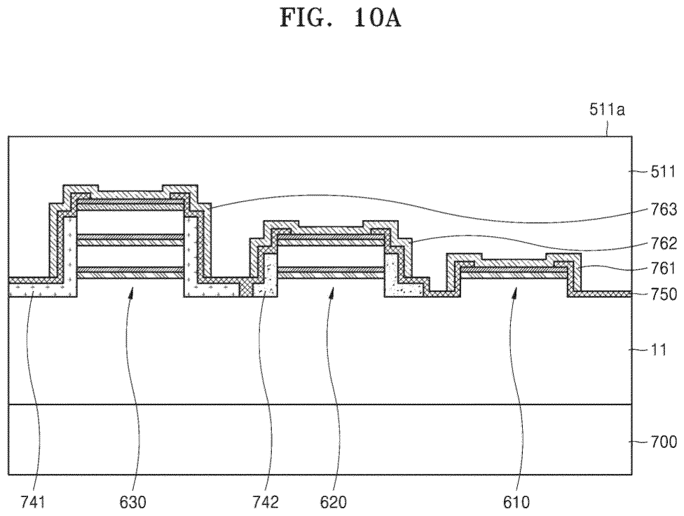

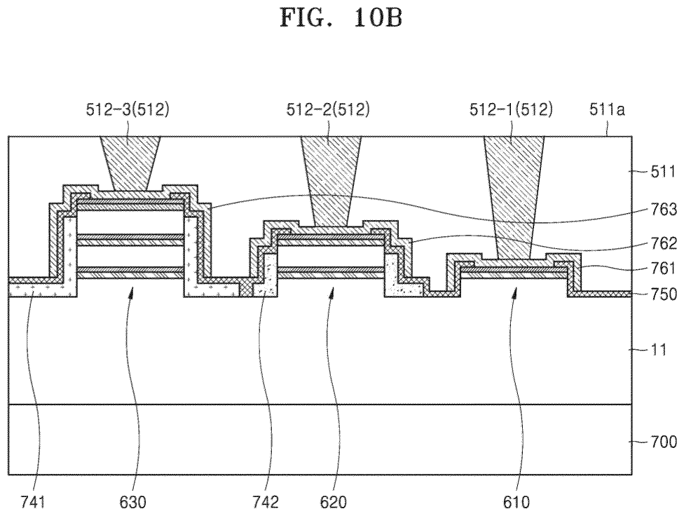

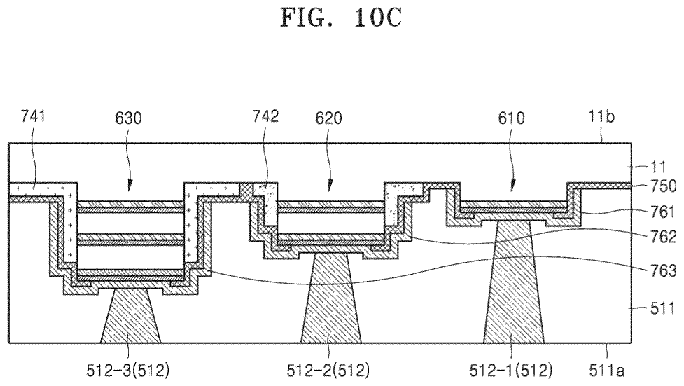

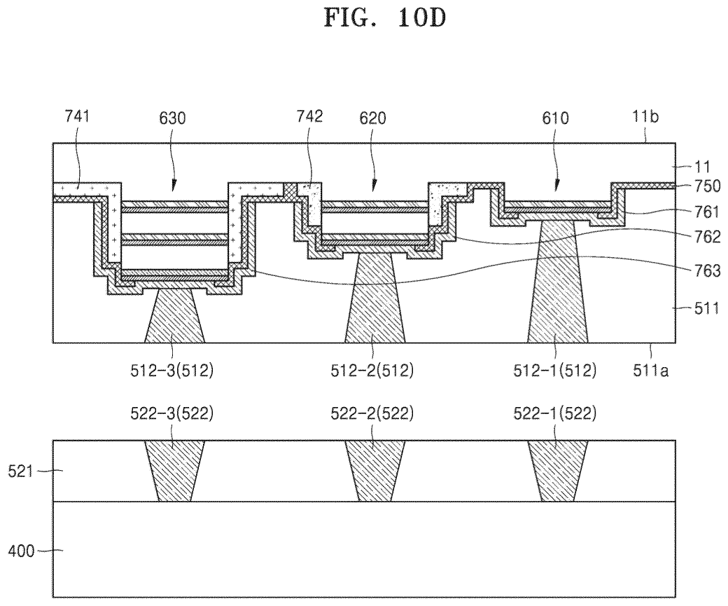

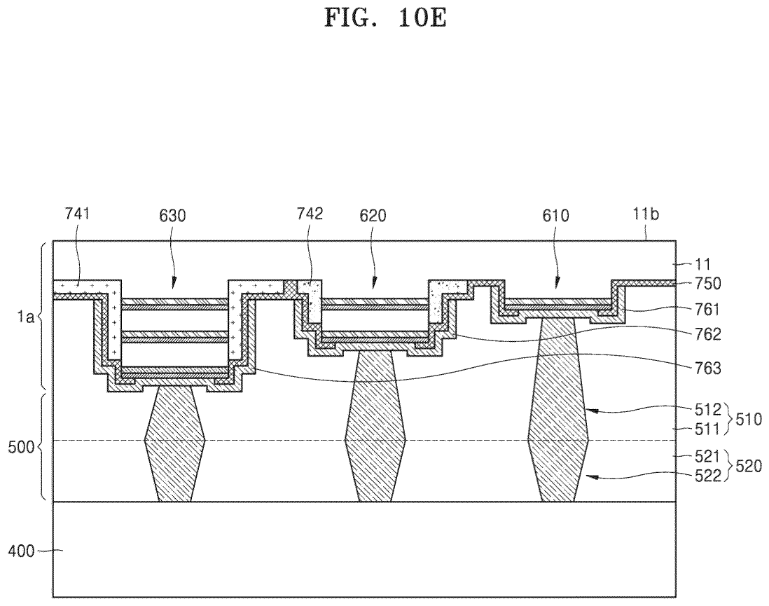

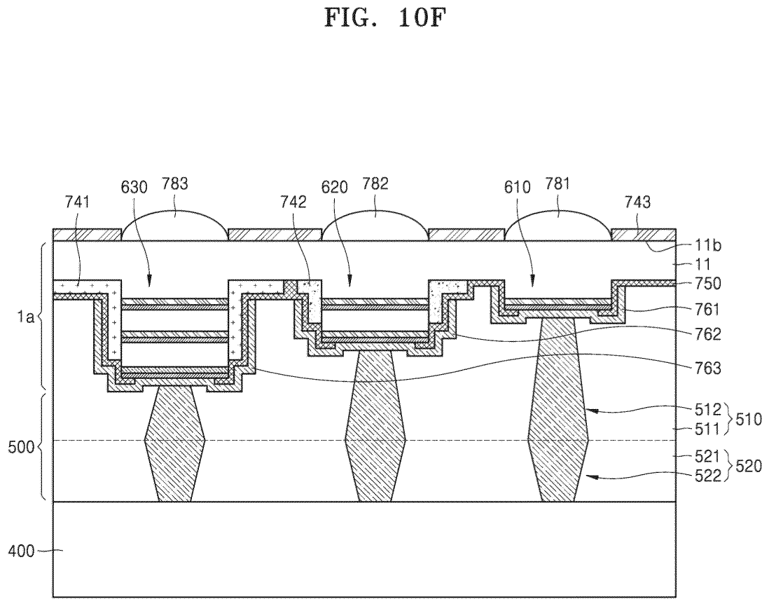

As shown in FIG. 5, the light-emitting device 1a is connected to the driving substrate 400 on which the drive circuit is provided via the connector 500, and thereby forming the display panel. FIGS. 10A to 10F are diagrams illustrating a method of manufacturing a display panel, according to one or more embodiments.

Referring to FIG. 10A, in the configuration shown in FIG. 9B, a first insulating layer 511 entirely covering the first, second, and third epitaxial structures 610, 620, and 630, the passivation layer 750, and the individual electrodes 761, 762, and 763 is formed. For example, the first insulating layer 511 may include SiO₂. As necessary, an upper surface 511a of the first insulating layer 511 may be polished by, for example, a CMP process, to be planarized. In FIG. 10A, reference numeral 700 denotes a growth substrate.

Referring to FIG. 10B, for example, through a Cu-damascene process, the three first conductive vias 512-1, 512-2, and 512-3 that are respectively connected to the first, second, and third individual electrodes 761, 762, and 763 through the first insulating layer 511 may be formed. For example, vias exposing the upper surfaces of the individual electrodes 761, 762, and 763 are formed by etching the first insulating layer 511, and then, the vias may be filled with an electrode material, e.g., copper (Cu). The three first conductive vias 512-1, 512-2, and 512-3 are exposed to the surface 511a of the first insulating layer 511. The first connector 510 (see FIG. 5) may be formed by the first insulating layer 511 and the first conductive vias 512-1, 512-2, and 512-3.

The structure shown in FIG. 10B is turned over and the growth substrate 700 is removed. Next, as shown in FIG. 10C, the exposed surface 11b of the common first conductive-type semiconductor layer 11 is polished to reduce a thickness of the common first conductive-type semiconductor layer 11.

Next, the second connection portion 520 (see FIG. 5) is formed on the driving substrate 400. Referring to FIG. 10D, a second insulating layer 521 covering one surface of the driving substrate 400 is formed. For example, the second insulating layer 521 may include SiO₂. As necessary, an upper surface of the second insulating layer 521 may be polished by, for example, a CMP process, to be planarized. For example, through a Cu-damascene process, three second conductive vias 522-1, 522-2, and 522-3 that are connected to bonding pads on the driving substrate 400 through the second insulating layer 521 and make pairs with the three first conductive vias 512-1, 512-2, and 512-3 may be formed. For example, vias exposing the bonding pads on the driving substrate 400 may be formed by etching the second insulating layer 521, and the vias may be filled with the electrode material, e.g., copper (Cu). The three second conductive vias 522-1, 522-2, and 522-3 are exposed to the surface of the second insulating layer 521. The second connecting portion 520 (see FIG. 5) may be formed by the second insulating layer 521 and the second conductive vias 522-1, 522-2, and 522-3.

As shown in FIG. 10E, the first conductive vias 512-1, 512-2, and 512-3 and three second conductive vias 522-1, 522-2, and 522-3 are aligned, and the first conductive vias 512-1, 512-2, and 512-3 and the three second conductive vias 522-1, 522-2, and 522-3 are bonded via, for example, C2C hybrid process. Accordingly, driving signals may be applied to the first, second, and third epitaxial structures 610, 620, and 630 from the drive circuit on the driving substrate 400.

Next, as shown in FIG. 10F, lenses 781 and 782 and a common electrode 743 may be formed on a surface 11b of the common first conductive-type semiconductor layer 11 in the light-emitting direction. The lenses 781, 782, and 783 are provided at positions aligned with the first, second, and third epitaxial structures 610, 620, and 630, respectively.

The lenses 781, 782, and 783 are provided at positions aligned with the first, second, and third epitaxial structures 610, 620, and 630, respectively. The method of forming the lenses 781, 782, and 783 is not particularly restricted. For example, a thermoplastic material may be stacked on the surface 11b of the first conductive-type semiconductor layer 11 to form a light transmission layer. For example, the thermoplastic material may include photoresist, polyester, acryl, epoxy, etc. The light transmission layer may have, for example, a cylindrical shape. Next, a thermal reflow process, for example, is performed to shape the light transmission layer of a rectangular shape into a dome-shaped lens shape. A curvature of the lenses 781, 782, and 783 may be adjusted by surface energy on the surface 11b of the first conductive-type semiconductor layer 11, a contact angle of the light emission layer, a thickness and width of the light emission layer, a temperature of the thermal reflow process, etc.

The electrode material may include, for example, Al, Ti, Pt, Ag, Au, Pd, TiW, ITO, Mo, or various combinations thereof. The electrode material may include, for example, Al, Ti, Pt, Ag, Au, Pd, TiW, ITO, Mo, or various combinations thereof.

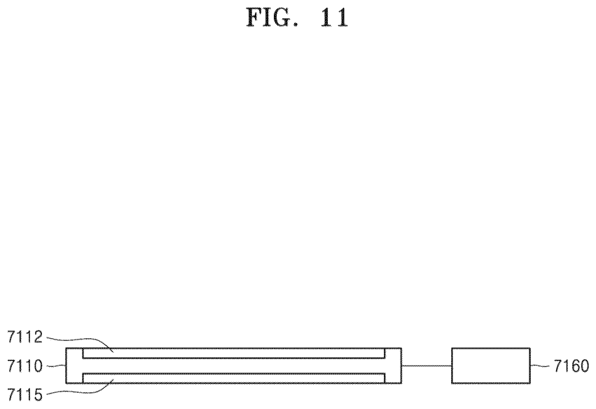

FIG. 11 is a schematic diagram of a display apparatus according to one or more embodiments. Referring to FIG. 11, the display apparatus may include a display panel 7110 and a controller 7160. The display panel 7110 includes an emission structure 7112, and a drive circuit 7115 performing on/off switching of the emission structure 7112. The emission structure 7112 may include a plurality of light-emitting devices described above with reference to FIGS. 1A to 4. A drive circuit 7115 may be provided on the driving substrate 400 shown in FIG. 5. The plurality of light-emitting devices may be arranged as, for example, a two-dimensional array. The drive circuit 7115 has a plurality of switching devices for individually switching on/off of the plurality of light-emitting devices. The controller 7160 inputs on/off switching signals for the plurality of light-emitting devices to the drive circuit 7115 according to an image signal.

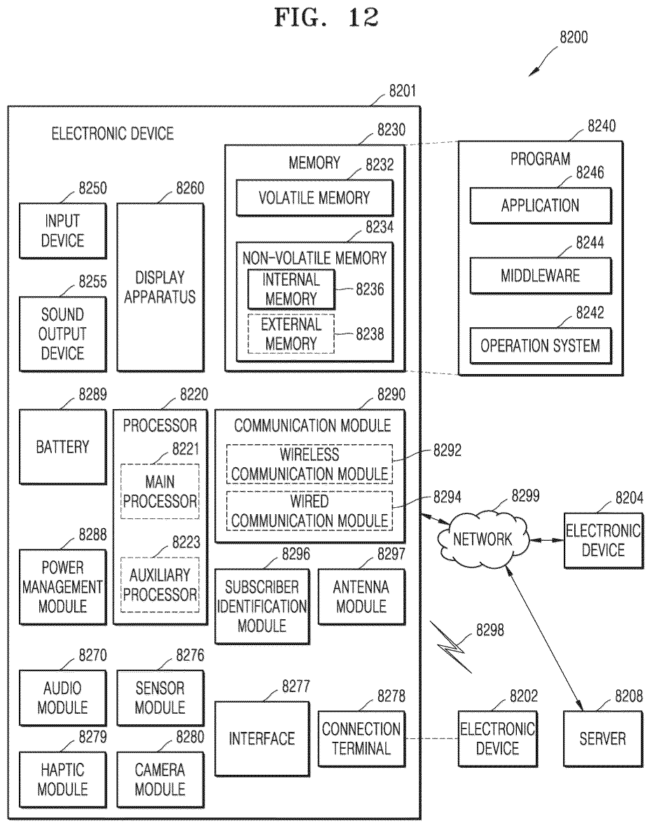

FIG. 12 is a block diagram of an electronic device including a display, according to one or more embodiments. Referring to FIG. 12, an electronic device 8201 may be provided in a network environment 8200. In the network environment 8200, the electronic device 8201 may communicate with another electronic device 8202 via a first network 8298 (short-range wireless communication network, etc.) or may communicate with another electronic device 8204 and/or a server 8208 via a second network 8299 (long distance wireless communication network, etc.). The electronic device 8201 may communicate with the electronic device 8204 via the server 8208. The electronic device 8201 may include a processor 8220, a memory 8230, an input device 8250, a sound output device 8255, a display apparatus 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. In the electronic device 8201, some of the elements may be omitted or another element may be added. Some of the elements may be configured as one integrated circuit. For example, the sensor module 8276 (a fingerprint sensor, an iris sensor, an illuminance sensor, etc.) may be embedded and implemented in the display apparatus 8260 (display, etc.)

The processor 8220 may control one or more elements (hardware, software elements, etc.) of the electronic device 8201 connected to the processor 8220 by executing software (program 8240, etc.), and may perform various data processes or operations. As a part of the data processing or operations, the processor 8220 may load a command and/or data received from another element (sensor module 8276, communication module 8290, etc.) to a volatile memory 8232, may process the command and/or data stored in the volatile memory 8232, and may store result data in a non-volatile memory 8234. The processor 8220 may include a main processor 8221 (central processing unit, application processor, etc.) and an auxiliary processor 8223 (graphic processing unit, image signal processor, sensor hub processor, communication processor, etc.) that may be operated independently from or along with the main processor 8221. The auxiliary processor 8223 may use less power than that of the main processor 8221, and may perform specified functions.

The auxiliary processor 8223, on behalf of the main processor 8221 while the main processor 8221 is in an inactive state (sleep state) or along with the main processor 8221 while the main processor 8221 is in an active state (application executed state), may control functions and/or states related to some (display apparatus 8260, sensor module 8276, communication module 8290, etc.) of the elements in the electronic device 8201. The auxiliary processor 8223 (image signal processor, communication processor, etc.) may be implemented as a part of another element (camera module 8280, communication module 8290, etc.) that is functionally related thereto.

The memory 8230 may store various data required by the elements (processor 8220, sensor module 8276, etc.) of the electronic device 8201. The data may include, for example, input data and/or output data about software (program 8240, etc.) and commands related thereto. The memory 8230 may include the volatile memory 8232 and/or the non-volatile memory 8234.

The program 8240 may be stored as software in the memory 8230, and may include an operation system 8242, middleware 8244, and/or an application 8246.

The input device 8250 may receive commands and/or data to be used in the elements (processor 8220, etc.) of the electronic device 8201, from outside (user, etc.) of the electronic device 8201. The input device 8250 may include a remote controller, a microphone, a mouse, a keyboard, and/or a digital pen (stylus pen).

The sound output device 8255 may output a sound signal to outside of the electronic device 8201. The sound output device 8255 may include a speaker and/or a receiver. The speaker may be used for a general purpose such as multimedia reproduction or record play, and the receiver may be used to receive a call. The receiver may be coupled as a part of the speaker or may be implemented as an independent device.

The display apparatus 8260 may provide visual information to outside of the electronic device 8201. The display apparatus 8260 may include a display, a hologram device, or a projector, and a control circuit for controlling the corresponding device. The display apparatus 8260 may include the display described with reference to FIG. 11. The display apparatus 8260 may include a touch circuitry set to sense a touch, and/or a sensor circuit (pressure sensor, etc.) that is set to measure a strength of a force generated by the touch.

The audio module 8270 may convert sound into an electrical signal or vice versa. The audio module 8270 may acquire sound through the input device 8250, or may output sound via the sound output device 8255 and/or a speaker and/or a headphone of another electronic apparatus (electronic device 8202, etc.) connected directly or wirelessly to the electronic device 8201.

The sensor module 8276 may sense an operating state (power, temperature, etc.) of the electronic device 8201, or an outer environmental state (user state, etc.), and may generate an electrical signal and/or data value corresponding to the sensed state. The sensor module 8276 may include a gesture sensor, a gyro-sensor, a pressure sensor, a magnetic sensor, an acceleration sensor, a grip sensor, a proximity sensor, a color sensor, an infrared (IR) ray sensor, a vivo sensor, a temperature sensor, a humidity sensor, and/or an illuminance sensor.

The interface 8277 may support one or more designated protocols that may be used in order for the electronic device 8201 to be directly or wirelessly connected to another electronic apparatus (electronic device 8202, etc.) The interface 8277 may include a high-definition multimedia interface (HDMI), a universal serial bus (USB) interface, an SD card interface, and/or an audio interface.

The connection terminal 8278 may include a connector by which the electronic device 8201 may be physically connected to another electronic apparatus (electronic device 8202, etc.). The connection terminal 8278 may include an HDMI connector, a USB connector, an SD card connector, and/or an audio connector (headphones connector, etc.).

The haptic module 8279 may convert the electrical signal into a mechanical stimulation (vibration, motion, etc.) or an electric stimulation that the user may sense through a tactile or motion sensation. The haptic module 8279 may include a motor, a piezoelectric device, and/or an electric stimulus device.

The camera module 8280 may capture a still image and a video. The camera module 8280 may include a lens assembly including one or more lenses, image sensors, image signal processors, and/or flashes. The lens assembly included in the camera module 8280 may collect light emitted from an object to be captured.

The power management module 8288 may manage the power supplied to the electronic device 8201. The power management module 8388 may be implemented as a part of a power management integrated circuit (PMIC).

The battery 8289 may supply electric power to components of the electronic device 8201. The battery 8289 may include a primary battery that is not rechargeable, a secondary battery that is rechargeable, and/or a fuel cell.

The communication module 8290 may support the establishment of a direct (wired) communication channel and/or a wireless communication channel between the electronic device 8201 and another electronic apparatus (electronic device 8202, electronic device 8204, server 8208, etc.), and execution of communication through the established communication channel. The communication module 8290 may be operated independently from the processor 8220 (application processor, etc.), and may include one or more communication processors that support the direct communication and/or the wireless communication. The communication module 8290 may include a wireless communication module 8292 (cellular communication module, a short-range wireless communication module, a global navigation satellite system (GNSS) communication module) and/or a wired communication module 8294 (local area network (LAN) communication module, a power line communication module, etc.). From among the communication modules, a corresponding communication module may communicate with another electronic apparatus via a first network 8298 (short-range communication network such as Bluetooth, WiFi direct, or infrared data association (IrDA)) or a second network 8299 (long-range communication network such as a cellular network, Internet, or computer network (LAN, WAN, etc.)). Such above various kinds of communication modules may be integrated as one element (single chip, etc.) or may be implemented as a plurality of elements (a plurality of chips) separately from one another. The wireless communication module 8292 may identify and authenticate the electronic device 8201 in a communication network such as the first network 8298 and/or the second network 8299 by using subscriber information (international mobile subscriber identifier (IMSI), etc.) stored in the subscriber identification module 8296.

The antenna module 8297 may transmit or receive the signal and/or power to/from outside (another electronic apparatus, etc.). An antenna may include a radiator formed as a conductive pattern formed on a substrate (PCB, etc.). The antenna module 8297 may include one or more antennas. When the antenna module 8297 includes a plurality of antennas, from among the plurality of antennas, an antenna that is suitable for the communication type used in the communication network such as the first network 8298 and/or the second network 8299 may be selected by the communication module 8290. The signal and/or the power may be transmitted between the communication module 8290 and another electronic apparatus via the selected antenna. Another component (RFIC, etc.) other than the antenna may be included as a part of the antenna module 8297.

Some of the elements may be connected to one another via the communication method among the peripheral devices (bus, general purpose input and output (GPIO), serial peripheral interface (SPI), mobile industry processor interface (MIPI), etc.) and may exchange signals (commands, data, etc.).

The command or data may be transmitted or received between the electronic device 8201 and the external electronic device 8204 via the server 8208 connected to the second network 8299. Other electronic devices 8202 and 8204 may be the devices that are the same as or different kinds from the electronic device 8201. All or some of the operations executed in the electronic device 8201 may be executed in one or more devices among the other electronic devices 8202, 8204, and 8208. For example, when the electronic device 8201 has to perform a certain function or service, the electronic device 8201 may request one or more other electronic apparatuses to perform some or entire function or service, instead of executing the function or service by itself. One or more electronic apparatuses receiving the request execute an additional function or service related to the request and may transfer a result of the execution to the electronic device 8201. To do this, for example, a cloud computing, a distributed computing, or a client-server computing technique may be used.

The above electronic device 8201 may be applied to various apparatuses. Various components of the electronic device 8201 described above may be appropriately modified according to the function of the device, and components suitable for performing the function of the device may be added. Application examples of the electronic device 8201 are described below.

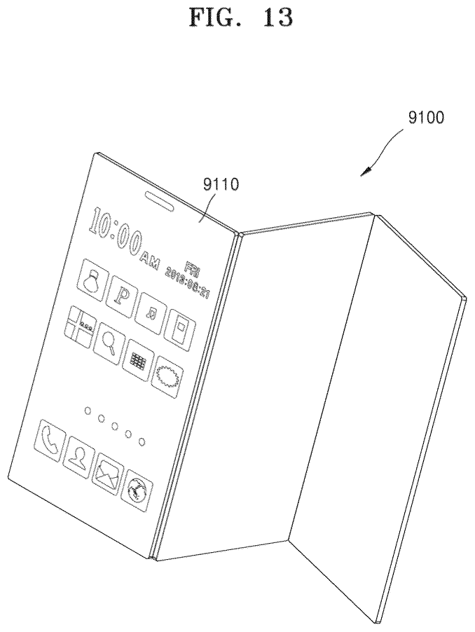

FIG. 13 is a diagram showing an example of a mobile device that is an example of the electronic device. A mobile device 9100 may include a display apparatus 9110. The display apparatus 9110 may include the display apparatus described with reference to FIG. 11. The display apparatus 9110 may have a foldable structure, e.g., multi-foldable structure.

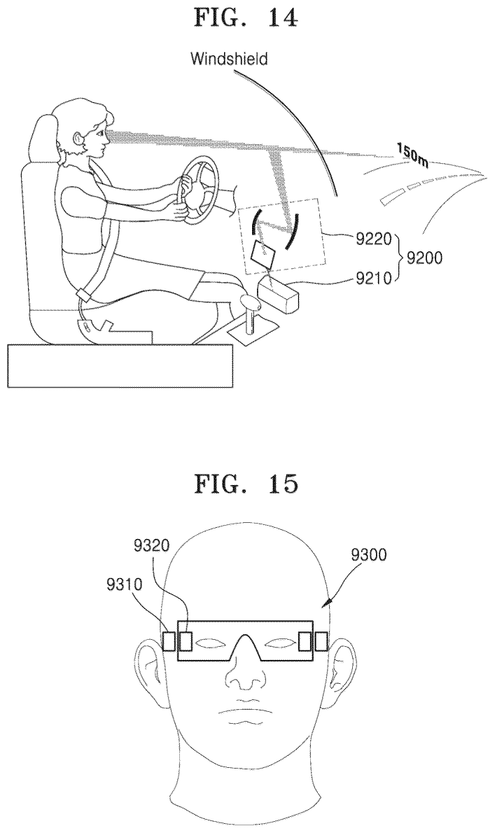

FIG. 14 is a diagram showing a head-up display apparatus for a vehicle, according to an application example of the electronic device. A head-up display apparatus 9200 for a vehicle may include a display 9210 provided in one region of the vehicle, and an optical path changing member 9220 that converts the optical path so that a driver is able to watch images generated by the display 9210. The display 9210 may include the display apparatus described with reference to FIG. 11.

FIG. 15 is a diagram showing an augmented reality (AR) glasses or virtual reality (VR) glasses, according to an application example of the electronic device. AR glasses (or VR glasses) 9300 may include a project system 9310 forming images, and a guiding element 9320 guiding the image from the project system 9310 to the eyes of a user. The project system 9310 may include the display apparatus described with reference to FIG. 11.

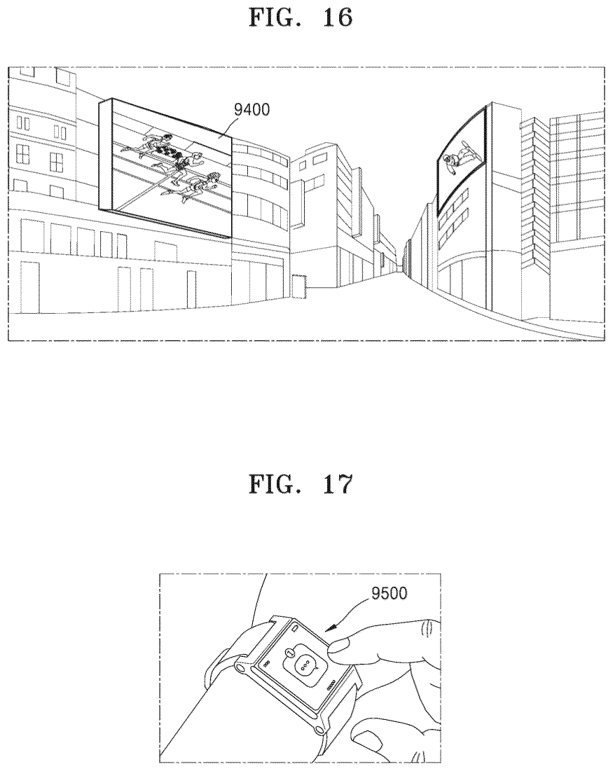

FIG. 16 is a diagram showing a relatively large-sized signage according to an application example of the electronic device. Signage 9400 may include the display apparatus described with reference to FIG. 11. The signage 9400 may be used in outdoor advertisement using a digital information display, and may control advertisement content via a communication network. The signage 9400 may be implemented via, for example, the electronic device described with reference to FIG. 12.

FIG. 17 is a diagram showing a wearable display according to an application example of the electronic device. A wearable display 9500 may include the display apparatus described with reference to FIG. 11. The wearable display 9500 may be implemented through the electronic device described with reference to FIG. 12.

The light-emitting device or the display including the light-emitting device according to one or more embodiments may be applied to various products such as a rollable television (TV), a stretchable display, etc.

While the light-emitting device has been particularly shown and described with reference to embodiments thereof, it will be understood by those of ordinary skill in the art that various changes in form and details may be made therein without departing from the spirit and scope as defined by the following claims and their equivalents. Therefore, the scope sought to be protected of the disclosure shall be defined by the appended claims.

According to one or more embodiments, the light-emitting device in which sub-pixels are horizontally arranged and electrodes do not pass through the emission structure and the display apparatus adopting the light-emitting device may be implemented.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope as defined by the following claims and their equivalents.

What is claimed is:

1. A light-emitting device comprising:
a first light-emitting portion comprising a first emission structure;
a second light-emitting portion comprising a first emission structure and a second emission structure that are sequentially stacked;
a third light-emitting portion comprising a first emission structure, a second emission structure, and a third emission structure that are sequentially stacked;
a first common electrode; and
a second common electrode,
wherein the first light-emitting portion, the second light-emitting portion, and the third light-emitting portion are spaced apart from each other,
wherein each of the first emission structure of the first light-emitting portion, the first emission structure and the second emission structure of the second light-emitting portion, and the first emission structure, the second emission structure, and the third emission structure of the third light-emitting portion comprises a first conductive-type semiconductor layer, an active layer, and a second conductive-type semiconductor layer that are sequentially stacked,
wherein the first emission structure of the first light-emitting portion, the first emission structure of the second light-emitting portion, and the first emission structure of the third light-emitting portion comprise a common first conductive-type semiconductor layer,
wherein the first common electrode electrically connects the common first conductive-type semiconductor layer to the first conductive-type semiconductor layer of the third emission structure of the third light-emitting portion, and the first common electrode comprises a first electrode material, and
wherein the second common electrode electrically connects the common first conductive-type semiconductor layer to the first conductive-type semiconductor layer of the second emission structure of the second light-emitting portion, and the second common electrode comprises a second electrode material that is different from the first electrode material.

2. The light-emitting device of claim 1, wherein the first electrode material and the second electrode material have etch selectivity with respect to different etchants.

3. The light-emitting device of claim 1, wherein a surface of the first conductive-type semiconductor layer, exposed between the first light-emitting portion, the second light-emitting portion, and the third light-emitting portion, is flat.

4. The light-emitting device of claim 3, wherein the first common electrode extends from the exposed surface of the common first conductive-type semiconductor layer along a side surface of the third light-emitting portion and contacts a side surface of the first conductive-type semiconductor layer of the third emission structure of the third light-emitting portion, and
wherein the second common electrode extends from the exposed surface of the common first conductive-type semiconductor layer along a side surface of the second light-emitting portion and contacts the side surface of the first conductive-type semiconductor layer of the second emission structure of the second light-emitting portion.

5. The light-emitting device of claim 4, wherein the first common electrode and the second common electrode partially overlap each other between the second light-emitting portion and the third light-emitting portion.

6. The light-emitting device of claim 1, further comprising:
interlayer insulating layers between the first emission structure and the second emission structure of the second light-emitting portion and between adjacent pairs of the first emission structure, the second emission structure, and the third emission structure of the third light-emitting portion.

7. The light-emitting device of claim 1, wherein the second conductive-type semiconductor layer forming an uppermost layer of the first light-emitting portion and the second conductive-type semiconductor layer forming an uppermost layer of the second light-emitting portion are surface-treated with a second conductive-type dopant.

8. The light-emitting device of claim 7, wherein a surface dopant concentration of the second conductive-type semiconductor layers that are surface-treated is greater than or equal to 3×10²⁰ cm⁻³.

9. The light-emitting device of claim 1, further comprising:
a passivation layer on the first light-emitting portion, the second light-emitting portion, the third light-emitting portion, the first common electrode, and the second common electrode, the passivation layer having openings that expose an upper surface of the second conductive-type semiconductor layer at an uppermost layer of the first light-emitting portion, an upper surface of the second conductive-type semiconductor layer at an uppermost layer of the second light-emitting portion, and an upper surface of the second conductive-type semiconductor layer at an uppermost layer of the third light-emitting portion; and
a first individual electrode, a second individual electrode, and a third individual electrode that contact the upper surface of the second conductive-type semiconductor layer at the uppermost layer of the first light-emitting portion, the upper surface of the second conductive-type semiconductor layer at the uppermost layer of the second light-emitting portion, and the upper surface of the second conductive-type semiconductor layer at the uppermost layer of the third light-emitting portion, respectively, via the openings.

10. The light-emitting device of claim 9, wherein the first individual electrode, the second individual electrode, and the third individual electrode extend from the upper surface of the second conductive-type semiconductor layer at the uppermost layer of the first light-emitting portion, the upper surface of the second conductive-type semiconductor layer at the uppermost layer of the second light-emitting portion, and the upper surface of the second conductive-type semiconductor layer at the uppermost layer of the third light-emitting portion along a side surface of the passivation layer.

11. A method of manufacturing a light-emitting device, the method comprising:
forming an epitaxial structure comprising a first emission structure, a second emission structure, and a third emission structure, each of the first emission structure, the second emission structure, and the third emission structure comprising a first conductive-type semiconductor layer, an active layer, and a second conductive-type semiconductor layer that are sequentially stacked;
forming a first epitaxial structure, a second epitaxial structure, and a third epitaxial structure that are spaced apart from each other by etching the epitaxial structure to the first conductive-type semiconductor layer of the first emission structure;
exposing the second conductive-type semiconductor layer of the first emission structure of the first epitaxial structure, the second conductive-type semiconductor layer of the second emission structure of the second epitaxial structure, and the second conductive-type semiconductor layer of the third emission structure of the third epitaxial structure;
forming a first common electrode extending from an exposed surface of the first conductive-type semiconductor layer of the first emission structure and contacting a side surface of the first conductive-type semiconductor layer of the third emission structure in the third epitaxial structure, the first common electrode comprising a first electrode material; and
forming a second common electrode extending from an exposed surface of the first conductive-type semiconductor layer of the first emission structure and contacting a side surface of the first conductive-type semiconductor layer of the second emission structure in the second epitaxial structure, the second common electrode comprising a second electrode material that is different from the first electrode material.

12. The method of claim 11, wherein the exposing the second conductive-type semiconductor layer of the first emission structure of the first epitaxial structure, the second conductive-type semiconductor layer of the second emission structure of the second epitaxial structure, and the second conductive-type semiconductor layer of the third emission structure of the third epitaxial structure comprises:
exposing the second conductive-type semiconductor layer of the third emission structure of the first epitaxial structure, the second conductive-type semiconductor layer of the third emission structure of the second epitaxial structure, and the second conductive-type semiconductor layer of the third emission structure of the third epitaxial structure;
exposing the second conductive-type semiconductor layer of the second emission structure of the first epitaxial structure and the second conductive-type semiconductor layer of the second emission structure of the second epitaxial structure by removing the third emission structure of the first epitaxial structure and the third emission structure of the second epitaxial structure; and
exposing the second conductive-type semiconductor layer of the first emission structure in the first epitaxial structure by removing the second emission structure of the first epitaxial structure.

13. The method of claim 12, wherein the forming the epitaxial structure comprises:
forming etch stop layers having different etching speeds between adjacent pairs of the first emission structure, the second emission structure, and the third emission structure.

14. The method of claim 11, wherein the forming the first common electrode comprises:
forming a first electrode material layer by depositing the first electrode material on the first epitaxial structure, the second epitaxial structure, and the third epitaxial structure and an exposed surface of the first conductive-type semiconductor layer of the first emission structure; and
removing the first electrode material on an upper surface of the first epitaxial structure, an upper surface of the second epitaxial structure, and an upper surface of the third epitaxial structure by a first etchant having an etch selectivity with respect to the first electrode material.

15. The method of claim 14, wherein the forming the second common electrode comprises:
forming a second electrode material layer by depositing the second electrode material on the first epitaxial structure, the second epitaxial structure, the third epitaxial structure, the first common electrode, and an exposed surface of the first conductive-type semiconductor layer of the first emission structure; and
removing, in the second electrode material layer, a part on the first epitaxial structure, a part on the upper surface of the second epitaxial structure, and a part on the third epitaxial structure, and a portion of a part on the first common electrode by using a second etchant having an etch selectivity with respective to the second electrode material.

16. The method of claim 11, wherein, from among the exposed second conductive-type semiconductor layer of the first epitaxial structure, the exposed second conductive-type semiconductor layer of the second epitaxial structure, and the exposed second conductive-type semiconductor layer of the third epitaxial structure, at least the second conductive-type semiconductor layer forming an uppermost layer of the first epitaxial structure and the second conductive-type semiconductor layer forming an uppermost layer of the second epitaxial structure are surface-treated by a second conductive-type dopant.

17. The method of claim 16, wherein a surface dopant concentration of the second conductive-type semiconductor layers that are surface-treated is 3×10²⁰ cm⁻³ or greater.

18. The method of claim 11, further comprising:
forming a passivation layer on the first epitaxial structure, the second epitaxial structure, the third epitaxial structure, the first common electrode, and the second common electrode, the passivation layer having openings exposing an upper surface of the second conductive-type semiconductor layer at an uppermost layer of the first epitaxial structure, an upper surface of the second conductive-type semiconductor layer at an uppermost layer of the second epitaxial structure, and an upper surface of the second conductive-type semiconductor layer at an uppermost layer of the third epitaxial structure; and
forming a first individual electrode, a second individual electrode, and a third individual electrode that contact the upper surface of the second conductive-type semiconductor layer at the uppermost layer of the first emission structure, the upper surface of the second conductive-type semiconductor layer at the uppermost layer of the second emission structure, and the upper surface of the second conductive-type semiconductor layer at the uppermost layer of the third emission structure, respectively, via the openings.

19. The method of claim 18, wherein the first individual electrode, the second individual electrode, and the third individual electrode extend from the upper surface of the second conductive-type semiconductor layer at the uppermost layer of the first epitaxial structure, the upper surface of the second conductive-type semiconductor layer at the uppermost layer of the second epitaxial structure, and the upper surface of the second conductive-type semiconductor layer at the uppermost layer of the third epitaxial structure along a side surface of the passivation layer.

20. A display apparatus comprising:
a display panel comprising light-emitting devices;
a drive circuit configured to switch the light-emitting devices on and off; and
at least one processor configured to input switching signals for the light-emitting devices to the drive circuit based on an image signal,
wherein at least one of the light-emitting devices comprises:
a first light-emitting portion comprising a first emission structure;
a second light-emitting portion comprising a first emission structure and a second emission structure that are sequentially stacked;
a third light-emitting portion comprising a first emission structure, a second emission structure, and a third emission structure that are sequentially stacked;
a first common electrode; and
a second common electrode,
wherein the first light-emitting portion, the second light-emitting portion, and the third light-emitting portion are spaced apart from each other,
wherein each of the first emission structure of the first light-emitting portion, the first emission structure and the second emission structure of the second light-emitting portion, and the first emission structure, the second emission structure, and the third emission structure of the third light-emitting portion comprises a first conductive-type semiconductor layer, an active layer, and a second conductive-type semiconductor layer that are sequentially stacked,
wherein the first emission structure of the first light-emitting portion, the first emission structure of the second light-emitting portion, and the first emission structure of the third light-emitting portion comprise a common first conductive-type semiconductor layer,
wherein the first common electrode electrically connects the common first conductive-type semiconductor layer to the first conductive-type semiconductor layer of the third emission structure of the third light-emitting portion, and the first common electrode comprises a first electrode material, and
wherein the second common electrode electrically connects the common first conductive-type semiconductor layer to the first conductive-type semiconductor layer of the second emission structure of the second light-emitting portion, and the second common electrode comprises a second electrode material that is different from the first electrode material.
